(19) United States
(12) Patent Application Publication
(10) Pub. No.: US 2026/0129895 A1
(43) Pub. Date: May 7, 2026

(54) NITRIDE SEMICONDUCTOR DEVICE

(71) Applicant: Panasonic Holdings Corporation, Osaka (JP)

(72) Inventors: NAOHIRO TSURUMI, Kyoto (JP); HIROYUKI HANDA, Osaka (JP); SATOSHI TAMURA, Osaka (JP)

(21) Appl. No.: 19/367,871

(22) Filed: Oct. 24, 2025

(30) Foreign Application Priority Data
Nov. 5, 2024 (JP) 2024-193597

(51) Int. Cl. H10D 30/47; H10D 62/85; H10D 64/00

(52) U.S. Cl. CPC H10D 30/475; H10D 62/8503; H10D 64/111

(57) ABSTRACT

A nitride semiconductor device includes a substrate a substrate, a semiconductor laminate disposed above the substrate and including a channel and a first and a second nitride semiconductor layers, a source electrode and a drain electrode each being in contact with the semiconductor laminate, a threshold adjustment layer located between the source electrode and the drain electrode, and a gate electrode disposed above the threshold adjustment layer. The second nitride semiconductor layer includes a first thin film portion located between the gate electrode and the source electrode and a first thick film portion that is located between the gate electrode and the drain electrode and is thicker than the first thin film portion. The threshold adjustment layer extends across the first thin film portion and the first thick film portion. An end of the threshold adjustment layer on the source electrode side is located on the first thin film portion.

### BACKGROUND

### 1. Technical Field

The present disclosure relates to a nitride semiconductor device.

### 2. Description of the Related Art

Patent Literature (PTL) 1 discloses a nitride semiconductor device including a two-dimensional electron gas (2DEG) as a channel. In the nitride semiconductor device disclosed in PTL 1, a p-type nitride semiconductor layer is provided so as to cover a side surface of the gate recess on the source electrode side, and a gate electrode is provided on an upper surface of the p-type nitride semiconductor layer. As a result, it is described that the parasitic capacitance generated between the gate electrode and the 2DEG can be reduced.

PTL 1: Japanese Patent No. 6742301

### SUMMARY

The nitride semiconductor device according to one aspect of the present disclosure includes: a substrate; a semiconductor laminate disposed above the substrate and including a channel; a source electrode and a drain electrode each being in contact with the semiconductor laminate; a threshold adjustment layer located between the source electrode and the drain electrode; and a gate electrode disposed above the threshold adjustment layer. The semiconductor laminate includes a first nitride semiconductor layer and a second nitride semiconductor layer disposed above the first nitride semiconductor layer, The second nitride semiconductor layer includes a first thin film portion located between the gate electrode and the source electrode in a plan view of the substrate and a first thick film portion that is located between the gate electrode and the drain electrode in a plan view of the substrate and is thicker than the first thin film portion. The threshold adjustment layer extends across the first thin film portion and the first thick film portion in a plan view of the substrate. An end of the threshold adjustment layer on the source electrode side is located on the first thin film portion.

The nitride semiconductor device according to another aspect of the present disclosure includes: a substrate; a semiconductor laminate disposed above the substrate and including a channel; a first electrode and a second electrode each being in contact with the semiconductor laminate; a first threshold adjustment layer located between the first electrode and the second electrode; a second threshold adjustment layer located between the first threshold adjustment layer and the second electrode; a first gate electrode disposed above the first threshold adjustment layer; and a second gate electrode disposed above the second threshold adjustment layer. The semiconductor laminate includes a first nitride semiconductor layer and a second nitride semiconductor layer disposed above the first nitride semiconductor layer. The second nitride semiconductor layer includes a first thin film portion located between the first gate electrode and the first electrode in a plan view of the substrate, a second thin film portion located between the second gate electrode and the second electrode in a plan view of the substrate, and a first thick film portion that is located between the first thin film portion and the second thin film portion in a plan view of the substrate and is thicker than both of the first thin film portion and the second thin film portion. The first threshold adjustment layer extends across the first thin film portion and the first thick film portion in a plan view of the substrate. The second threshold adjustment layer extends across the second thin film portion and the first thick film portion in a plan view of the substrate. An end of the first threshold adjustment layer on the first electrode side is located on the first thin film portion. An end of the second threshold adjustment layer on the second electrode side is located on the second thin film portion.

A nitride semiconductor device according to another aspect of the present disclosure includes: a substrate; an n-type third nitride semiconductor layer disposed above the substrate; a p-type fourth nitride semiconductor layer disposed above the third nitride semiconductor layer; a semiconductor laminate disposed to cover an inner surface of an opening penetrating the fourth nitride semiconductor layer and reaching the third nitride semiconductor layer and an upper side of the fourth nitride semiconductor layer, and including a channel; a first electrode and a second electrode each being in contact with the semiconductor laminate; a threshold adjustment layer located between the first electrode and the second electrode; a gate electrode disposed above the threshold adjustment layer; and a drain electrode disposed below the substrate. The opening is located between the first electrode and the second electrode in a plan view of the substrate. The first electrode and the second electrode are each a source electrode and are electrically connected to each other. The semiconductor laminate includes a first nitride semiconductor layer and a second nitride semiconductor layer provided above the first nitride semiconductor layer. The second nitride semiconductor layer includes a first thin film portion located between the gate electrode and the first electrode in a plan view of the substrate, a second thin film portion located between the gate electrode and the second electrode in a plan view of the substrate and a first thick film portion that is located between the first thin film portion and the second thin film portion in a plan view of the substrate and is thicker than both of the first thin film portion and the second thin film portion. The threshold adjustment layer extends across the first thin film portion and the first thick film portion and extends across the second thin film portion and the first thick film portion in a plan view of the substrate. An end of the threshold adjustment layer on the first electrode side is located on the first thin film portion. An end of the threshold adjustment layer on the second electrode side is located on the second thin film portion.

### BRIEF DESCRIPTION OF THE DRAWINGS

FIG. 1 is a cross-sectional view of a nitride semiconductor device according to a first exemplary embodiment;

FIG. 2 is a cross-sectional view of a nitride semiconductor device according to a modification of the first exemplary embodiment;

FIG. 3 is a cross-sectional view of a nitride semiconductor device according to a second exemplary embodiment;

FIG. 4A is a cross-sectional view of a nitride semiconductor device according to a comparative example;

FIG. 4B is a graph showing capacitance characteristics of the nitride semiconductor devices according to the comparative example and the example;

FIG. 5 is a cross-sectional view of a nitride semiconductor device according to Modification 1 of the second exemplary embodiment;

FIG. 6 is a cross-sectional view of a nitride semiconductor device according to Modification 2 of a second exemplary embodiment;

FIG. 7 is a cross-sectional view of a nitride semiconductor device according to Modification 3 of the second exemplary embodiment;

FIG. 8 is a cross-sectional view of a nitride semiconductor device according to Modification 4 of the second exemplary embodiment;

FIG. 9 is a cross-sectional view of a nitride semiconductor device according to Modification 5 of the second exemplary embodiment;

FIG. 10A is a plan view of a nitride semiconductor device according to the second exemplary embodiment;

FIG. 10B is a cross-sectional view of the nitride semiconductor device taken along line XB-XB in FIG. 10A;

FIG. 11 is a cross-sectional view of a nitride semiconductor device according to a third exemplary embodiment;

FIG. 12 is a cross-sectional view of a nitride semiconductor device according to Modification 1 of the third exemplary embodiment;

FIG. 13A is a plan view of a nitride semiconductor device according to Modification 1 of the third exemplary embodiment;

FIG. 13B is a cross-sectional view of the nitride semiconductor device taken along line XIIIB-XIIIB in FIG. 13A;

FIG. 13C is a cross-sectional view of the nitride semiconductor device taken along line XIIIC-XIIIC in FIG. 13A;

FIG. 14 is a cross-sectional view of a nitride semiconductor device according to Modification 2 of the third exemplary embodiment;

FIG. 15 is a cross-sectional view of a nitride semiconductor device according to a fourth exemplary embodiment;

FIG. 16 is a cross-sectional view of a nitride semiconductor device according to Modification 1 of the fourth exemplary embodiment;

FIG. 17 is a cross-sectional view of a nitride semiconductor device according to Modification 2 of the fourth exemplary embodiment;

FIG. 18 is a cross-sectional view of a nitride semiconductor device according to a fifth exemplary embodiment;

FIG. 19 is a cross-sectional view of a nitride semiconductor device according to Modification 1 of the fifth exemplary embodiment; and

FIG. 20 is a cross-sectional view of a nitride semiconductor device according to Modification 2 of the fifth exemplary embodiment.

### DETAILED DESCRIPTIONS

In the conventional nitride semiconductor device described above, when a high drain voltage is applied in an off state, an electric field tends to concentrate on an end of the gate recess on the drain electrode side. This leads to a problem of an increase in the leakage current and a decrease in the withstand voltage between the gate and the drain.

Therefore, the present disclosure provides a nitride semiconductor device capable of achieving both reduction in parasitic capacitance and improvement in withstand voltage.

### Summary of present disclosure

The nitride semiconductor device according to a first aspect of the present disclosure includes: a substrate; a semiconductor laminate disposed above the substrate and including a channel; a source electrode and a drain electrode each being in contact with the semiconductor laminate; a threshold adjustment layer located between the source electrode and the drain electrode; and a gate electrode disposed above the threshold adjustment layer, wherein the semiconductor laminate includes a first nitride semiconductor layer and a second nitride semiconductor layer disposed above the first nitride semiconductor layer, the second nitride semiconductor layer includes: a first thin film portion located between the gate electrode and the source electrode in a plan view of the substrate; and a first thick film portion that is located between the gate electrode and the drain electrode in a plan view of the substrate and is thicker than the first thin film portion, the threshold adjustment layer extends across the first thin film portion and the first thick film portion in a plan view of the substrate, and an end of the threshold adjustment layer on the source electrode side is located on the first thin film portion.

When the nitride semiconductor device is turned off, generation of a two-dimensional electron gas (2DEG) in the vicinity of the interface between the first thin film portion and the first nitride semiconductor layer is suppressed. The end of the threshold adjustment layer on the source electrode side is located on the first thin film portion, and thus the area where the threshold adjustment layer and the 2DEG face each other is reduced. Therefore, the parasitic capacitance between the gate and the source can be reduced. In addition, the threshold adjustment layer extends across the first thin film portion and the thick film portion, and thus the electric field caused by the high drain voltage during OFF is dispersed to the end of the threshold adjustment layer on the drain electrode side and the end of the first thin film portion on the drain electrode side with which the threshold adjustment layer is in contact. The electric field concentration is suppressed, and thus the leakage current is reduced, and the withstand voltage between the gate and the drain can be increased. As described above, according to the nitride semiconductor device of the present aspect, it is possible to achieve both the reduction of the parasitic capacitance and the improvement of the withstand voltage.

The nitride semiconductor device according to the second aspect of the present disclosure is the nitride semiconductor device according to the first aspect, in which the source electrode is disposed on the first thin film portion, and the drain electrode is disposed on the first thick film portion.

As a result, the generation of 2DEG on the source electrode side is suppressed during OFF, and thus the parasitic capacitance between the gate and the source can be further reduced. In addition, the distance between the source electrode and the 2DEG can be shortened, and thus the contact resistance to the channel can be reduced.

The nitride semiconductor device according to the third aspect of the present disclosure is the nitride semiconductor device according to the first aspect, in which the second nitride semiconductor layer further includes a second thick film portion located between the first thin film portion and the source electrode in a plan view of the substrate.

As a result, the concentration of 2DEG generated in the vicinity of the interface between the second thick film portion and the first nitride semiconductor layer can be increased, and thus the on-resistance can be reduced.

The nitride semiconductor device according to the fourth aspect of the present disclosure is the nitride semiconductor device according to the third aspect, in which the source electrode is disposed on the second thick film portion, and the drain electrode is disposed on the first thick film portion.

As a result, the concentration of 2DEG generated immediately below each of the source electrode and the drain electrode can be increased, and thus the on-resistance can be reduced.

The nitride semiconductor device according to the fifth aspect of the present disclosure is the nitride semiconductor device according to the first aspect, in which the second nitride semiconductor layer further includes a second thin film portion that is located between the first thick film portion and the drain electrode in a plan view of the substrate and is thinner than the first thick film portion, the source electrode is disposed on the first thin film portion, and the drain electrode is disposed on the second thin film portion.

As a result, the distance between each of the source electrode and the drain electrode and the 2DEG can be shortened, and thus the contact resistance to the channel can be reduced.

The nitride semiconductor device according to the sixth aspect of the present disclosure is the nitride semiconductor device according to any one of the first to fifth aspects, in which the second nitride semiconductor layer further includes a first inclined portion located between the first thin film portion and the first thick film portion in a plan view of the substrate and having an inclined upper surface.

As a result, the electric field caused by the high drain voltage during OFF is easily dispersed along the upper surface of the first inclined portion, and thus the withstand voltage can be further increased.

The nitride semiconductor device according to the seventh aspect of the present disclosure is the nitride semiconductor device according to the third aspect or the fourth aspect, in which the second nitride semiconductor layer further includes: a first inclined portion located between the first thin film portion and the first thick film portion and having an inclined upper surface in a plan view of the substrate; and a second inclined portion located between the first thin film portion and the second thick film portion and having an inclined upper surface in a plan view of the substrate, and an inclination of the inclined upper surface of the first inclined portion is gentler than an inclination of the inclined upper surface of the second inclined portion.

As a result, the electric field caused by the high drain voltage during OFF is easily dispersed along the upper surface of the first inclined portion, and thus the withstand voltage can be further increased. In addition, the inclination of the upper surface of the second inclined portion is steep, and thus the distance between the gate and the source can be shortened, and the nitride semiconductor device can be downsized.

The nitride semiconductor device according to the eighth aspect of the present disclosure is the nitride semiconductor device according to any one of the first to seventh aspects, in which the threshold adjustment layer is a p-type nitride semiconductor layer.

As a result, the potential of the conduction band edge of the channel is raised in the direction immediately below the p-type nitride semiconductor layer. The carrier concentration in the direction immediately below the p-type nitride semiconductor layer can be reduced, and the threshold of the transistor can be shifted to the positive side. Therefore, the nitride semiconductor device can be operated as a normally-off type field effect transistor (FET).

The nitride semiconductor device according to the ninth aspect of the present disclosure is the nitride semiconductor device according to any one of the first to eighth aspects, in which the nitride semiconductor device can be divided into an active region and an inactive region in a plan view of the substrate, the source electrode and the drain electrode are disposed in the active region, the nitride semiconductor device further includes a drain pad disposed in the inactive region and electrically connected to the drain electrode, the first thick film portion, the first thin film portion, and the threshold adjustment layer are all further located between the source electrode and the drain pad in a plan view of the substrate, and the threshold adjustment layer extends across the first thin film portion and the first thick film portion between the source electrode and the drain pad in a plan view of the substrate.

As a result, the electric field caused by the high drain voltage applied to the drain pad can be dispersed, and thus the withstand voltage can be further increased.

The nitride semiconductor device according to the tenth aspect of the present disclosure includes: a substrate; a semiconductor laminate disposed above the substrate and including a channel; a first electrode and a second electrode each being in contact with the semiconductor laminate; a first threshold adjustment layer located between the first electrode and the second electrode; a second threshold adjustment layer located between the first threshold adjustment layer and the second electrode; a first gate electrode disposed above the first threshold adjustment layer; and a second gate electrode disposed above the second threshold adjustment layer, wherein the semiconductor laminate includes a first nitride semiconductor layer and a second nitride semiconductor layer disposed above the first nitride semiconductor layer, the second nitride semiconductor layer includes: a first thin film portion located between the first gate electrode and the first electrode in a plan view of the substrate; a second thin film portion located between the second gate electrode and the second electrode in a plan view of the substrate; and a first thick film portion that is located between the first thin film portion and the second thin film portion in a plan view of the substrate and is thicker than both of the first thin film portion and the second thin film portion, the first threshold adjustment layer extends across the first thin film portion and the first thick film portion in a plan view of the substrate, the second threshold adjustment layer extends across the second thin film portion and the first thick film portion in a plan view of the substrate, an end of the first threshold adjustment layer on the first electrode side is located on the first thin film portion, and an end of the second threshold adjustment layer on the second electrode side is located on the second thin film portion.

When the nitride semiconductor device is turned off, generation of a two-dimensional electron gas (2DEG) in the vicinity of the interface between the first thin film portion and the first nitride semiconductor layer is suppressed. The end of the first threshold adjustment layer on the first electrode side is located on the first thin film portion, and thus the area where the first threshold adjustment layer and the 2DEG face each other is reduced. Therefore, the parasitic capacitance between the first gate electrode and the first electrode can be reduced. Similarly, the parasitic capacitance between the second gate electrode and the second electrode can also be reduced. In addition, the first threshold adjustment layer extends across the first thin film portion and the first thick film portion, and thus although a high voltage is applied to the second electrode during OFF, the electric field caused by the voltage is dispersed to the end of the first threshold adjustment layer on the second electrode side and the end of the first thin film portion in contact with the first threshold adjustment layer on the second electrode side. Similarly, the second threshold adjustment layer extends across the second thin film portion and the first thick film portion, and thus although a high voltage is applied to the first electrode during OFF, the electric field caused by the voltage is dispersed to the end of the second threshold adjustment layer on the first electrode side and the end of the second thin film portion on the first electrode side in contact with the second threshold adjustment layer. As described above, although a high voltage is applied to either the first electrode or the second electrode during OFF, the electric field concentration is suppressed, and thus the leakage current is reduced and the withstand voltage can be increased. As described above, according to the nitride semiconductor device of the present aspect, it is possible to achieve both the reduction of the parasitic capacitance and the improvement of the withstand voltage.

The nitride semiconductor device according to the 11th aspect of the present disclosure is the nitride semiconductor device according to the tenth aspect, in which the first electrode is disposed on the first thin film portion, and the second electrode is disposed on the second thin film portion.

As a result, the generation of 2DEG between the first electrode and the first threshold adjustment layer and between the second electrode and the second threshold adjustment layer is suppressed during OFF, and thus the parasitic capacitance can be further reduced. In addition, the distance between each of the first electrode and the second electrode and the 2DEG can be shortened, and thus the contact resistance to the channel can be reduced.

The nitride semiconductor device according to the 12th aspect of the present disclosure is the nitride semiconductor device according to the tenth aspect, in which the second nitride semiconductor layer further includes: a second thick film portion located between the first thin film portion and the first electrode in a plan view of the substrate; and a third thick film portion located between the second thin film portion and the second electrode in a plan view of the substrate.

As a result, the concentration of 2DEG generated in the vicinity of the interface between each of the second thick film portion and the third thick film portion and the first nitride semiconductor layer can be increased, and thus the on-resistance can be reduced.

The nitride semiconductor device according to the 13th aspect of the present disclosure is the nitride semiconductor device according to the 12th aspect, in which the first electrode is disposed on the second thick film portion, and the second electrode is disposed on the third thick film portion.

As a result, the concentration of 2DEG generated immediately below each of the first electrode and the second electrode can be increased, and thus the on-resistance can be reduced.

The nitride semiconductor device according to the 14th aspect of the present disclosure is the nitride semiconductor device according to any one of the tenth to 13th aspects, in which the second nitride semiconductor layer further includes: a first inclined portion located between the first thin film portion and the first thick film portion and having an inclined upper surface in a plan view of the substrate; and a third inclined portion located between the second thin film portion and the first thick film portion and having an inclined upper surface in a plan view of the substrate.

As a result, the electric field caused by the high voltage during OFF is easily dispersed along the upper surface of the first inclined portion or the second inclined portion, and thus the withstand voltage can be further increased.

The nitride semiconductor device according to the 15th aspect of the present disclosure is the nitride semiconductor device according to any one of the tenth to 14th aspects, further comprising: an n-type third nitride semiconductor layer disposed above the substrate; a p-type fourth nitride semiconductor layer disposed above the third nitride semiconductor layer; and a drain electrode disposed below the substrate, in which the semiconductor laminate is disposed so as to cover an inner surface of an opening penetrating the fourth nitride semiconductor layer and reaching the third nitride semiconductor layer and an upper side of the fourth nitride semiconductor layer, the opening is located between the first electrode and the second electrode in a plan view of the substrate, the first electrode and the second electrode are each a source electrode and are electrically connected to each other, the first gate electrode and the first threshold adjustment layer are located between a bottom surface of the opening and the first electrode in a plan view of the substrate, and the second gate electrode and the second threshold adjustment layer are located between a bottom surface of the opening and the second electrode in a plan view of the substrate.

As a result, the nitride semiconductor device can be achieved as a so-called vertical device. It is possible to achieve a high withstand voltage and a large current of the nitride semiconductor device.

The nitride semiconductor device according to the 16th aspect of the present disclosure is the nitride semiconductor device according to the 15th aspect, further including: a p-type fifth nitride semiconductor layer disposed above the semiconductor laminate at a location overlapping the bottom surface of the opening in a plan view of the substrate; and a third electrode disposed above the fifth nitride semiconductor layer and set to the same potential as the source electrode.

As a result, the line of electric force extending from the drain electrode can be terminated in the p-type fifth nitride semiconductor layer, and thus the parasitic capacitance between the gate and the drain can be reduced. Therefore, according to the present aspect, the rise time and the fall time of the voltage and the current can be shortened, and thus a nitride semiconductor device capable of high-speed operation can be achieved. In addition, the switching loss can be reduced, thus suppressing the total loss although a high-speed operation is performed, and thus a low-loss power device can be achieved.

The nitride semiconductor device according to a 17th aspect of the present disclosure is the nitride semiconductor device according to any one of the tenth to 16th aspects, in which the first threshold adjustment layer and the second threshold adjustment layer are each a p-type nitride semiconductor layer.

As a result, the carrier concentration in the direction immediately below the p-type nitride semiconductor layer can be reduced, and the threshold of the transistor can be shifted to the positive side. Therefore, the nitride semiconductor device can be operated as a normally-off type FET.

The nitride semiconductor device according to the 18th aspect of the present disclosure is the nitride semiconductor device according to any one of the tenth to 17th aspects, in which the nitride semiconductor device can be divided into an active region and an inactive region in a plan view of the substrate; the first electrode and the second electrode are disposed in the active region; the nitride semiconductor device further includes: a first pad disposed in the inactive region and electrically connected to the first electrode, and a second pad disposed in the inactive region and electrically connected to the second electrode; all of the first thick film portion, the first thin film portion, and the first threshold adjustment layer are further located between the first electrode and the first pad in a plan view of the substrate; the first threshold adjustment layer extends across the first thin film portion and the first thick film portion between the first electrode and the first pad in a plan view of the substrate; all of the first thick film portion, the second thin film portion, and the second threshold adjustment layer are further located between the second electrode and the second pad in a plan view of the substrate; and the second threshold adjustment layer extends across the second thin film portion and the first thick film portion between the second electrode and the second pad in a plan view of the substrate.

As a result, the electric field caused by the high voltage applied to the first pad or the second pad can be dispersed, and thus the withstand voltage can be further increased.

The nitride semiconductor device according to the 19th aspect of the present disclosure includes: a substrate; an n-type third nitride semiconductor layer disposed above the substrate; a p-type fourth nitride semiconductor layer disposed above the third nitride semiconductor layer; a semiconductor laminate disposed so as to cover an inner surface of an opening penetrating the fourth nitride semiconductor layer and reaching the third nitride semiconductor layer and an upper side of the fourth nitride semiconductor layer, and including a channel; a first electrode and a second electrode each being in contact with the semiconductor laminate; a threshold adjustment layer located between the first electrode and the second electrode; a gate electrode disposed above the threshold adjustment layer; and a drain electrode disposed below the substrate, wherein the opening is located between the first electrode and the second electrode in a plan view of the substrate, the first electrode and the second electrode are each a source electrode and are electrically connected to each other, the semiconductor laminate includes: a first nitride semiconductor layer; and a second nitride semiconductor layer disposed above the first nitride semiconductor layer, the second nitride semiconductor layer includes: a first thin film portion located between the gate electrode and the first electrode in a plan view of the substrate; a second thin film portion located between the gate electrode and the second electrode in a plan view of the substrate; and a first thick film portion that is located between the first thin film portion and the second thin film portion in a plan view of the substrate and is thicker than both of the first thin film portion and the second thin film portion, the threshold adjustment layer extends across the first thin film portion and the first thick film portion and extends across the second thin film portion and the first thick film portion in a plan view of the substrate, an end of the threshold adjustment layer on the first electrode side is located on the first thin film portion, and an end of the threshold adjustment layer on the second electrode side is located on the second thin film portion.

When the nitride semiconductor device is turned off, generation of 2DEG in the vicinity of the interface between each of the first thin film portion and the second thin film portion and the first nitride semiconductor layer is suppressed. The end of the threshold adjustment layer on the first electrode side is located on the first thin film portion and the end of the threshold adjustment layer on the second electrode side is located on the second thin film portion, and thus the area where the threshold adjustment layer and the 2DEG face each other is reduced. Therefore, the parasitic capacitance between the gate electrode and each of the first electrode and the second electrode can be reduced. In addition, the nitride semiconductor device according to the present aspect is a so-called vertical device and is excellent in withstand voltage. As described above, according to the nitride semiconductor device of the present aspect, it is possible to achieve both the reduction of the parasitic capacitance and the improvement of the withstand voltage.

The nitride semiconductor device according to the 20th aspect of the present disclosure is the nitride semiconductor device according to the 19th aspect, in which the first electrode is disposed on the first thin film portion, and the second electrode is disposed on the second thin film portion.

As a result, the generation of 2DEG between each of the first electrode and the second electrode and the threshold adjustment layer is suppressed during OFF, and thus the parasitic capacitance can be further reduced. In addition, the distance between each of the first electrode and the second electrode and the 2DEG can be shortened, and thus the contact resistance to the channel can be reduced.

The nitride semiconductor device according to the 21st aspect of the present disclosure is the nitride semiconductor device according to the 19th aspect, in which the second nitride semiconductor layer further includes: a second thick film portion located between the first thin film portion and the first electrode in a plan view of the substrate; and a third thick film portion located between the second thin film portion and the second electrode in a plan view of the substrate.

As a result, the concentration of 2DEG generated in the vicinity of the interface between each of the second thick film portion and the third thick film portion and the first nitride semiconductor layer can be increased, and thus the on-resistance can be reduced.

The nitride semiconductor device according to the 22nd aspect of the present disclosure is the nitride semiconductor device according to the 21st aspect, in which the first electrode is disposed on the second thick film portion, and the second electrode is disposed on the third thick film portion.

As a result, the concentration of 2DEG generated immediately below each of the first electrode and the second electrode can be increased, and thus the on-resistance can be reduced.

The nitride semiconductor device according to the 23rd aspect of the present disclosure is the nitride semiconductor device according to any one of the 19th to 22nd aspects, in which the second nitride semiconductor layer further includes: a first inclined portion located between the first thin film portion and the first thick film portion in a plan view of the substrate and having an inclined upper surface; and a third inclined portion located between the second thin film portion and the first thick film portion in a plan view of the substrate and having an inclined upper surface.

As a result, the electric field caused by the high voltage during OFF is easily dispersed along the upper surface of the first inclined portion or the second inclined portion, and thus the withstand voltage can be further increased.

Hereinafter, exemplary embodiments will be specifically described with reference to the drawings.

The exemplary embodiments described hereinafter provide comprehensive or specific examples. Numerical values, shapes, materials, constituent elements, arrangement locations and connection modes of the constituent elements, manufacturing processes, the order of the manufacturing processes, and the like shown in the following exemplary embodiments are merely examples, and are not intended to limit the present disclosure. In addition, among the constituent elements in the following exemplary embodiments, constituent elements not recited in the independent claims are described as arbitrary constituent elements.

In addition, each of the drawings is a schematic view, and is not necessarily strictly illustrated. Therefore, for example, scales and the like are not necessarily matched in the respective drawings. In addition, in each drawing, substantially identical components are denoted by identical reference signs, and the redundant description will be omitted or simplified.

In addition, in the present specification, the term indicating the relationship between elements such as parallel and orthogonal, the term indicating the shape of an element such as a rectangle, and the numerical range are not expressions representing only a strict meaning, but are expressions meaning to include a substantially equivalent range, for example, a difference of approximately several%.

In addition, in the present specification, the “thickness direction” of the substrate refers to a direction perpendicular to the main surface of the substrate. The thickness direction is the same as the laminating direction of the semiconductor layers, and is also referred to as “vertical direction”. In addition, a direction parallel to the main surface of the substrate may be referred to as a “lateral direction”. The “vertical” semiconductor device means a device in which a main path of a current such as a drain current or a forward current is vertical, that is, a device in which a main current passes through a substrate in the vertical direction. A “lateral” semiconductor device means a device in which the main path of current, such as drain current or forward current, is lateral, i.e., the main current does not pass through the substrate.

In addition, the side on which the heterostructure is provided with respect to the substrate is regarded as “upper side” or “top side”, and the opposite side is regarded as “lower side” or “bottom side”. In the present description, the terms “upper side” and “lower side” do not refer to an upper direction (vertically upward) and a lower direction (vertically downward) in absolute space recognition, but are used as terms defined by a relative location relationship based on a laminating order in a laminating configuration. In addition, the terms “upper side” and “lower side” are not only applied to a case where two components are spaced apart from each other and another component is present between the two components, but are also applied to a case where two components are disposed in close contact with each other and are adjacent to each other.

In addition, in the present specification, unless otherwise specified, “plan view” refers to when viewed from a direction perpendicular to the main surface of the substrate of the semiconductor device, that is, when the main surface of the substrate is viewed from the front.

In addition, in the present specification, “A and B overlap in a plan view” means that at least a part of A and at least a part of B overlap. That is, a case where only a part of A and only a part of B overlap, a case where all of A overlap B, a case where all of B overlap A, and a case where A and B completely overlap each other are included.

In addition, the n-type and the p-type indicate the conductivity types of the semiconductor, and are conductivity types having opposite polarities to each other. The n⁺-type indicates a state in which an n-type dopant is added to a semiconductor at a high concentration, that is, a so-called heavy dope. In addition, the n⁻-type represents a state in which an n-type dopant is added to a semiconductor at a low concentration, that is, so-called light dope. Both the n⁺-type and the n⁻-type are examples of the n-type, and the n⁺-type and the n⁻-type may be described as the n-type without being distinguished from each other. In addition, the same applies to the p-type, the p⁺-type, and the p⁻-type.

In addition, in the present specification, the “main component” means a component having the highest content ratio among all the components constituting the member. For example, a component having a content ratio of 50% or more is a main component. The component is a material, an element, a compound, or the like. In addition, “the member A is composed of the component B” or “the member A is composed of the component B” means that the member A substantially contains only the component B. However, in addition to the component B, the member A may include impurities that cannot be prevented from being mixed in manufacturing.

In addition, in the present specification, AlGaN represents ternary mixed crystal AlₓGa₁₋ₓN (0 < x < 1). Hereinafter, the multicomponent mixed crystal is abbreviated as an arrangement of constituent element symbols, for example, AlInN, GaInN, and the like. For example, AlₓGa_{1-x-y}In_{y}N (0 < x < 1, 0 < y < 1, and 0 < x + y < 1), which is an example of a nitride semiconductor, is abbreviated as AlGaInN. x, 1-x-y, and y represent composition ratios of Al, Ga, and In, respectively.

In addition, in the present specification, ordinal numbers such as “first” and “second” do not mean the number or order of constituent elements unless otherwise specified, and are used for the purpose of avoiding confusion and distinguishing the same type of constituent elements.

### First exemplary embodiment

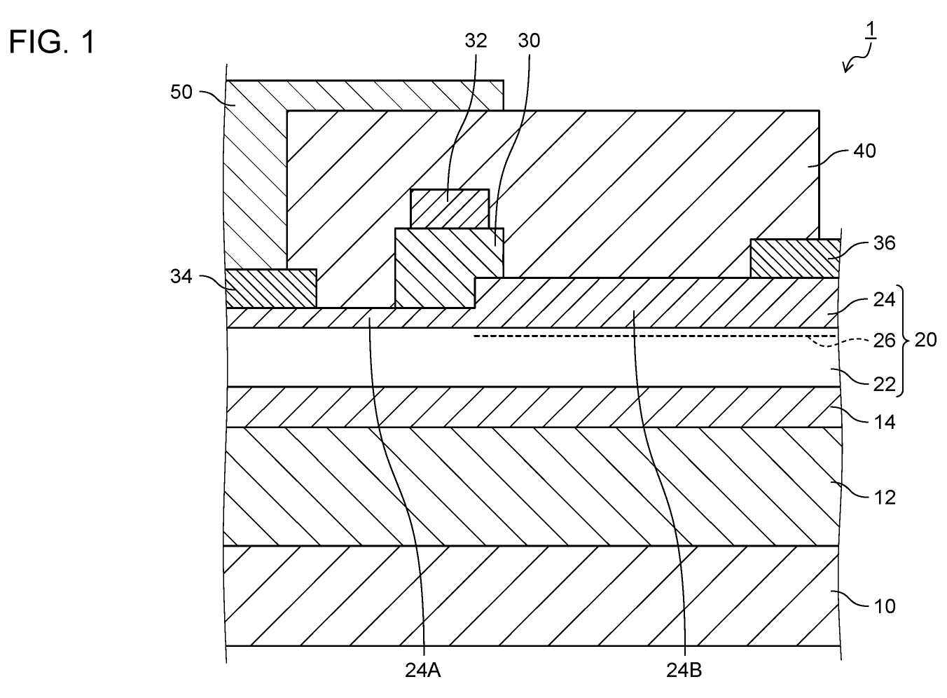

First, a configuration of a nitride semiconductor device according to a first exemplary embodiment will be described with reference to FIG. 1.

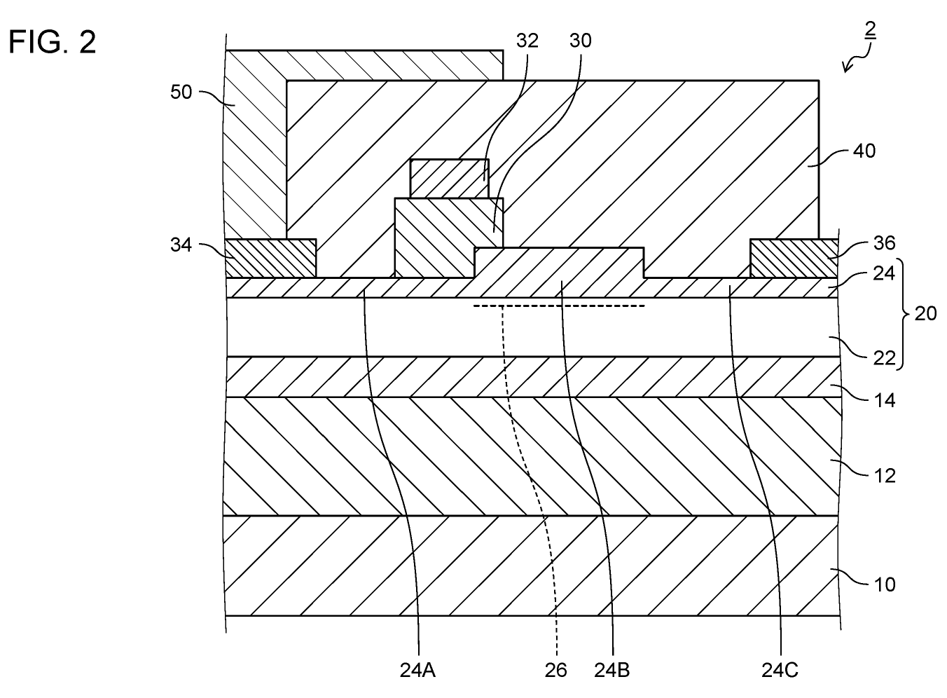

FIG. 1 is a cross-sectional view of nitride semiconductor device 1 according to the present exemplary embodiment. In FIG. 1, each component such as a semiconductor layer, an insulating layer, and an electrode included in nitride semiconductor device 1 is hatched to represent a cross section. Hatching representing a cross section is omitted for electron transit layer 22. The same applies to other cross-sectional views after FIG. 2.

Nitride semiconductor device 1 illustrated in FIG. 1 is a normally-off type lateral FET. That is, the threshold voltage of nitride semiconductor device 1 is larger than 0 V. In nitride semiconductor device 1, for example, source electrode 34 is grounded, and a positive potential is applied to drain electrode 36. When a potential less than the threshold value such as 0 V or a negative potential is applied to gate electrode 32, nitride semiconductor device 1 is in a non-conductive state, that is, turned off, and no current flows between source electrode 34 and drain electrode 36. When a positive potential exceeding the threshold voltage is applied to gate electrode 32, nitride semiconductor device 1 is in a conductive state, that is, turned on, and a current flows from drain electrode 36 toward source electrode 34. The current flowing from drain electrode 36 toward source electrode 34 in the ON state is also referred to as a drain current. The drain current flows in a direction parallel to the main surface of substrate 10, that is, in the lateral direction.

Nitride semiconductor device 1 according to the present exemplary embodiment is a nitride semiconductor device in which a semiconductor layer including a channel contains a nitride semiconductor as a main component. Specifically, each of buffer layer 12, back barrier layer 14, electron transit layer 22, electron supply layer 24, and p-type gate layer 30 contains a nitride semiconductor as a main component.

Nitride semiconductor device 1 is a device having an AlGaN/GaN heterostructure. Spontaneous polarization and piezoelectric polarization generated on the (0001) plane of GaN generate 2DEG 26 having a high concentration in the vicinity of the hetero interface. For this reason, there is a feature that a sheet carrier concentration of 1 × 10¹³ cm⁻² or more is obtained in the vicinity of the hetero interface despite the undoped state. Nitride semiconductor device 1 is a high electron mobility transistor (HEMT) including 2DEG 26 as a channel.

As illustrated in FIG. 1, nitride semiconductor device 1 includes substrate 10, buffer layer 12, back barrier layer 14, semiconductor laminate 20, p-type gate layer 30, gate electrode 32, source electrode 34, drain electrode 36, interlayer insulating layer 40, and source field plate 50.

Substrate 10 is a substrate made of the nitride semiconductor. The planar view shape of substrate 10 is, for example, rectangular, but is not limited thereto. Substrate 10 is, for example, a substrate made of n⁺-type GaN having a thickness of 300 μm and a carrier concentration of 5 × 10¹⁸ cm⁻³. Substrate 10 may be a Si substrate, a SiC substrate, a ZnO substrate, or the like. In addition, substrate 10 may be an insulating substrate such as sapphire or diamond. Alternatively, substrate 10 may be a semiconductor substrate having conductivity due to addition of n-type impurities, or may be a conductive substrate such as a graphite substrate including graphene.

Buffer layer 12 is provided above substrate 10. Buffer layer 12 is, for example, a film consisting of undoped GaN having a thickness of 7 μm. Buffer layer 12 may be provided in contact with the upper surface of substrate 10, or another nitride semiconductor layer may be provided between buffer layer 12 and substrate 10. The term “undoped” means that a dopant that changes the polarity of the nitride semiconductor to n-type or p-type is not doped.

Buffer layer 12 may be an insulating layer or a semi-insulating layer. For example, buffer layer 12 may be a film consisting of carbon-doped GaN (C-GaN). The carbon concentration of buffer layer 12 is, for example, 3 × 10¹⁷ cm⁻³ or more, and may be 1 × 10¹⁸ cm⁻³ or more. Buffer layer 12 may include n-type impurities such as Si. The concentration of the n-type impurity included in buffer layer 12 is lower than the carbon concentration and the oxygen concentration of buffer layer 12, and may be, for example, less than or equal to 5 × 10¹⁶ cm⁻³, or less than or equal to 2 × 10¹⁶ cm⁻³.

Back barrier layer 14 is provided above buffer layer 12. Back barrier layer 14 consists of, for example, an undoped AlGaN layer. Back barrier layer 14 may be an insulating layer or a semi-insulating layer. For example, back barrier layer 14 may be a film consisting of carbon-doped AlGaN (C-AlGaN). The carbon concentration of back barrier layer 14 is, for example, 3 × 10¹⁷ cm⁻³ or more, but may be 1 × 10¹⁸ cm⁻³ or more. In addition, back barrier layer 14 may include two layers of an undoped layer not intentionally doped with impurities and a layer doped with carbon.

Providing buffer layer 12 and back barrier layer 14 can suppress so-called punch-through in which electrons leak from 2DEG 26 to substrate 10. Thus, the withstand voltage of nitride semiconductor device 1 can be increased. At least one of buffer layer 12 and back barrier layer 14 may not be provided.

Semiconductor laminate 20 is provided above substrate 10 and includes a channel. Semiconductor laminate 20 is provided on the upper surface of back barrier layer 14. In the present exemplary embodiment, semiconductor laminate 20 includes electron transit layer 22 and electron supply layer 24. In addition, semiconductor laminate 20 includes 2DEG 26 as a channel.

Electron transit layer 22 is an example of a first nitride semiconductor layer. Specifically, electron transit layer 22 is provided on the upper surface of back barrier layer 14. Electron transit layer 22 is, for example, a film consisting of undoped GaN having a thickness of 150 nm. Electron transit layer 22 is assumed to be undoped, but may be partially made into an n-type by Si doping or the like.

Electron transit layer 22 includes 2DEG 26 as a channel. Specifically, 2DEG 26 serving as a channel is generated in the vicinity of the interface between electron transit layer 22 and electron supply layer 24. 2DEG 26 extends parallel to the main surface of substrate 10 along the interface between electron transit layer 22 and electron supply layer 24.

Although not illustrated in FIG. 1, an AlN layer having a thickness of about 1 nm is provided between electron transit layer 22 and electron supply layer 24. The AlN layer is an example of the nitride semiconductor layer included in semiconductor laminate 20. As a result, the alloy scattering is suppressed, the electron mobility of the channel is improved, and the on-resistance can be reduced. The AlN layer is not necessarily required.

Electron supply layer 24 is an example of a second nitride semiconductor layer provided above electron transit layer 22. Specifically, electron supply layer 24 is provided so as to cover the upper surface of electron transit layer 22. Electron supply layer 24 is, for example, a film consisting of undoped AlGaN. Electron supply layer 24 has a band gap larger than that of electron transit layer 22. Therefore, an AlGaN/GaN hetero interface is formed between electron supply layer 24 and electron transit layer 22. Electron supply layer 24 supplies electrons to a channel (2DEG 26) formed in electron transit layer 22.

As illustrated in FIG. 1, electron supply layer 24 includes thin film portion 24A and thick film portion 24B thicker than thin film portion 24A. Thin film portion 24A and thick film portion 24B are integrally formed, and have the same composition. That is, the Al composition ratios of thin film portion 24A and thick film portion 24B are the same, and are, for example, between 10% and 50%, but may be between 15% and 25%.

Thin film portion 24A is an example of a first thin film portion, and is located between gate electrode 32 and source electrode 34 in a plan view of substrate 10. In the present exemplary embodiment, thin film portion 24A is further provided at a location overlapping p-type gate layer 30 and a location overlapping source electrode 34 in a plan view. Thin film portion 24A is provided with a substantially uniform film thickness continuously from a location overlapping p-type gate layer 30 to a location overlapping source electrode 34.

Thick film portion 24B is an example of a first thick film portion, and is located between gate electrode 32 and drain electrode 36 in a plan view of substrate 10. In the present exemplary embodiment, thick film portion 24B is further provided at a location overlapping p-type gate layer 30 and a location overlapping drain electrode 36 in a plan view. Thick film portion 24B is provided with a substantially uniform film thickness continuously from a location overlapping p-type gate layer 30 to a location overlapping drain electrode 36.

The film thickness of thin film portion 24A is, for example, less than or equal to half of the film thickness of thick film portion 24B, but may be less than or equal to 1/3. The lower limit value of the film thickness of thin film portion 24A is, for example, 10 nm, but may be 6 nm. As an example, the film thickness of thin film portion 24A can be set to 20 nm.

The film thickness of thick film portion 24B depends on the composition of electron supply layer 24. For example, when the Al composition ratio is 20%, the upper limit value of the thickness of thick film portion 24B is 70 nm. This makes it possible to suppress the occurrence of misfit dislocations and cracks. The upper limit value of the thickness of thick film portion 24B tends to decrease as the Al composition ratio increases. For example, when the Al composition ratio is 25%, the upper limit value of the thickness of thick film portion 24B is 45 nm, and when the Al composition ratio is 30%, the upper limit value of the thickness of thick film portion 24B is 22 nm.

A boundary between thin film portion 24A and thick film portion 24B overlaps p-type gate layer 30 in a plan view of substrate 10. Thin film portion 24A and thick film portion 24B form a step, and p-type gate layer 30 is provided so as to cover the step. The side wall of thick film portion 24B located at the boundary is, for example, perpendicular to the main surface of substrate 10.

P-type gate layer 30 is an example of a threshold adjustment layer, and is a p-type nitride semiconductor layer provided between source electrode 34 and drain electrode 36. P-type gate layer 30 extends over thin film portion 24A and thick film portion 24B in a plan view of substrate 10. Specifically, p-type gate layer 30 continuously covers the upper surface of thin film portion 24A, the side wall of thick film portion 24B located at the boundary between thin film portion 24A and thick film portion 24B, and the upper surface of thick film portion 24B. In addition, an end of p-type gate layer 30 on source electrode 34 side is located on thin film portion 24A. In the present exemplary embodiment, thin film portion 24A is provided between the end of p-type gate layer 30 on source electrode 34 side and source electrode 34 and to a portion immediately below source electrode 34. The end of p-type gate layer 30 on drain electrode 36 side is located on thick film portion 24B. P-type gate layer 30 is disposed apart from each of source electrode 34 and drain electrode 36, and is electrically separated from them. The upper surface of p-type gate layer 30 is a flat surface, but a step corresponding to the step between thin film portion 24A and thick film portion 24B may be provided.

P-type gate layer 30 is, for example, a film consisting of p-type GaN having a thickness of 200 nm and a carrier concentration of 5 × 10¹⁷ cm⁻³. The thickness and the carrier concentration of p-type gate layer 30 are merely examples, and can be appropriately changed. P-type gate layer 30 may be a film consisting of p-type AlGaN.

P-type gate layer 30 is provided, and thus the potential of the conduction band edge of the channel is raised. As a result, the carrier concentration immediately below gate electrode 32 can be reduced, and the threshold voltage of the FET can be shifted to the positive side. Therefore, nitride semiconductor device 1 can be easily achieved as a normally-off type FET.

Gate electrode 32 is provided above p-type gate layer 30. Gate electrode 32 is electrically connected to p-type gate layer 30. Specifically, gate electrode 32 is provided in contact with the upper surface of p-type gate layer 30. In the present exemplary embodiment, gate electrode 32 extends across thin film portion 24A and thick film portion 24B in a plan view of substrate 10. An end of gate electrode 32 on source electrode 34 side overlaps thin film portion 24A in a plan view, and an end of gate electrode 32 on drain electrode 36 side overlaps thick film portion 24B in a plan view.

Gate electrode 32 is formed using, for example, a conductive material such as metal. For example, gate electrode 32 may be made of a material, such as p-type GaN, which is ohmic-connected to the p-type nitride semiconductor layer, but is not limited thereto, and a material that is in Schottky contact with the p-type nitride semiconductor layer may be used. For example, Pd, a Ni-based material, WSi, Au, or the like can be used.

Source electrode 34 and drain electrode 36 are provided in contact with semiconductor laminate 20 above substrate 10. Source electrode 34 and drain electrode 36 are provided so as to sandwich p-type gate layer 30 and gate electrode 32 therebetween. Specifically, source electrode 34 is electrically connected to electron transit layer 22 and provided away from p-type gate layer 30 and gate electrode 32. Source electrode 34 is provided on the thin film portion 24A. Drain electrode 36 is electrically connected to electron transit layer 22 and is provided away from p-type gate layer 30 and gate electrode 32. Drain electrode 36 is provided on thick film portion 24B.

Each of source electrode 34 and drain electrode 36 is formed using a conductive material such as metal. As a material of each of source electrode 34 and drain electrode 36, for example, a material that is ohmic-connected to an n-type nitride semiconductor layer such as n-type GaN by heat treatment, such as Ti/Al (laminated structure of Ti layer and Al layer), can be used. Source electrode 34 and drain electrode 36 are formed in the same step using the same material, for example.

At least one of source electrode 34 and drain electrode 36 may be provided so as to be in contact with electron transit layer 22. Specifically, a source opening and a drain opening that penetrate electron supply layer 24 and expose electron transit layer 22 may be provided. Source electrode 34 may be provided so as to cover the inner surface of the source opening, and drain electrode 36 may be provided so as to cover the inner surface of the drain opening, and each of source electrode 34 and drain electrode 36 may be in contact with 2DEG 26 exposed on the inner surface of each opening. As a result, the contact resistance can be reduced, and thus the on-resistance can be reduced.

Interlayer insulating layer 40 is provided above gate electrode 32. Specifically, interlayer insulating layer 40 is provided so as to cover gate electrode 32, p-type gate layer 30, electron supply layer 24, source electrode 34, and drain electrode 36. Interlayer insulating layer 40 has, for example, a single layer or laminated structure of an insulating film such as SiN, SiO₂, SiON, or Al₂O₃.

Source field plate 50 is provided above interlayer insulating layer 40, and is connected to source electrode 34 via an opening provided in interlayer insulating layer 40. Source field plate 50 is formed using a conductive material such as metal. For example, source field plate 50 is a plating film consisting of Au, for example.

In the present exemplary embodiment, source field plate 50 overlaps gate electrode 32 in a plan view of substrate 10. Source field plate 50 extends to drain electrode 36 side beyond gate electrode 32 from a location overlapping source electrode 34 in a plan view of substrate 10. Source field plate 50 can relax an electric field applied between the gate and the drain. Source field plate 50 does not overlap drain electrode 36 in a plan view.

Source field plate 50 also functions as a source wiring that electrically connects a source pad (not illustrated) and source electrode 34. Although not illustrated in FIG. 1, a drain wiring and a drain pad electrically connected to drain electrode 36, a gate wiring and a gate pad electrically connected to gate electrode 32, and the like may be provided above interlayer insulating layer 40.

### Effects and the like

As described above, in nitride semiconductor device 1 according to the present exemplary embodiment, electron supply layer 24 includes thin film portion 24A and thick film portion 24B. As a result, the concentration of 2DEG 26 generated in the vicinity of the interface between electron supply layer 24 and electron transit layer 22 can be varied depending on the site.

Polarization for generating 2DEG 26 includes spontaneous polarization caused by atomic arrangement of GaN and piezoelectric polarization caused by a lattice constant difference between electron supply layer 24 consisting of AlGaN and electron transit layer 22 consisting of GaN. The piezoelectric polarization varies depending on the composition and film thickness of electron supply layer 24 consisting of AlGaN. Therefore, the concentration of 2DEG 26 can be changed by adjusting at least one of the composition and the film thickness of electron supply layer 24 consisting of AlGaN. For example, decreasing the film thickness of electron supply layer 24 decreases the concentration of 2DEG 26, and increasing the film thickness of electron supply layer 24 increases the concentration of 2DEG 26.

In the present exemplary embodiment, the concentration of 2DEG 26 generated in the vicinity of the interface between thick film portion 24B having a large film thickness and electron transit layer 22 can be increased, and thus the on-resistance can be reduced. In contrast, it is possible to suppress generation of 2DEG 26 in the vicinity of the interface between thin film portion 24A and electron transit layer 22. For example, when a voltage equal to or higher than the threshold voltage is not applied to gate electrode 32, it is possible to prevent 2DEG 26 from being generated in the vicinity of the interface between thin film portion 24A and electron transit layer 22, or to sufficiently lower the concentration. As a result, it is possible to reduce the parasitic capacitance generated between gate electrode 32 and source electrode 34 during OFF.

In nitride semiconductor device 1, p-type gate layer 30 is provided across thin film portion 24A and thick film portion 24B in a plan view. The electric field caused by the high drain voltage during OFF is dispersed in the end of p-type gate layer 30 on drain electrode 36 side and the end of thin film portion 24A on drain electrode 36 side with which p-type gate layer 30 is in contact. The electric field concentration is suppressed, and thus the leakage current is reduced, and the withstand voltage between the gate and the drain can be increased. As described above, according to nitride semiconductor device 1 of the present exemplary embodiment, it is possible to achieve both the reduction of the parasitic capacitance and the improvement of the withstand voltage.

In addition, source electrode 34 is provided on thin film portion 24A, and thus the distance between the hetero interface between electron transit layer 22 and electron supply layer 24 and source electrode 34 is shortened. This can reduce the contact resistance between source electrode 34 and 2DEG 26. Therefore, according to nitride semiconductor device 1 of the present exemplary embodiment, the on-resistance can be reduced.

### Production method

Nitride semiconductor device 1 configured as described above is produced, for example, by the following method.

First, a nitride semiconductor is crystal-grown on the main surface of substrate 10 by epitaxial growth such as metal oxide vapor phase epitaxy (MOVPE) or hydride vapor phase epitaxy (HVPE). For example, buffer layer 12, back barrier layer 14, electron transit layer 22, and electron supply layer 24 are continuously formed in this order on the main surface of substrate 10. Thereafter, the film thickness of electron supply layer 24 is partially reduced by removing a part of electron supply layer 24 by dry etching or the like. Thus, thin film portion 24A is formed. Thereafter, p-type gate layer 30 is formed by an epitaxial growth method such as an MOVPE method or an HVPE method so as to cover at least the boundary between thin film portion 24A and thick film portion 24B. P-type gate layer 30 is entirely formed so as to cover the upper surfaces of thin film portion 24A and thick film portion 24B in contact with each other. Then, p-type gate layer 30 is patterned into a predetermined shape by dry etching or the like.

Then, a metal film is formed so as to cover p-type gate layer 30 by electron beam evaporation, sputtering, or the like, and an unnecessary portion is removed by etching, lift-off, or the like, thereby forming gate electrode 32. Further, a metal film is formed so as to cover the upper surfaces of thin film portion 24A and thick film portion 24B, and unnecessary portions are removed by etching, lift-off, or the like, thereby forming source electrode 34 and drain electrode 36. Either the formation of gate electrode 32 or the formation of source electrode 34 and drain electrode 36 may be performed first. In addition, source electrode 34 and drain electrode 36 may be formed in different steps.

Then, gate electrode 32, source electrode 34, and drain electrode 36 are formed, and then interlayer insulating layer 40 is formed. Interlayer insulating layer 40 is formed by, for example, a plasma CVD method, an atomic layer deposition method, or the like. After interlayer insulating layer 40 is formed, an opening is formed in interlayer insulating layer 40 by dry etching or the like to expose at least a part of source electrode 34 and drain electrode 36. Thereafter, source field plate 50 and the drain wiring (not illustrated) are formed so as to fill the opening. Source field plate 50 and the drain wiring are formed by, for example, sequentially depositing Ti, Al, Ni, or the like by sputtering, electron beam vapor deposition, or the like, and then performing Au plating.

As described above, nitride semiconductor device 1 illustrated in FIG. 1 can be produced. The above-described method for producing nitride semiconductor device 1 is merely an example, and is not particularly limited.

[Modifications] Then, a modification of the first exemplary embodiment will be described. Hereinafter, differences from the first exemplary embodiment will be mainly described, and description of common points will be omitted or simplified.

FIG. 2 is a cross-sectional view of nitride semiconductor device 2 according to the present modification. As illustrated in FIG. 2, nitride semiconductor device 2 is different from nitride semiconductor device 1 illustrated in FIG. 1 in that electron supply layer 24 further includes thin film portion 24C.

Thin film portion 24C is an example of a second thin film portion, and is located between thick film portion 24B and drain electrode 36 in a plan view of substrate 10. In the present exemplary embodiment, thin film portion 24C is further provided at a location overlapping drain electrode 36 in a plan view. Thin film portion 24C is provided with a substantially uniform film thickness continuously from an end of thick film portion 24B to a location overlapping drain electrode 36. The film thickness of thin film portion 24C may be the same as or different from the film thickness of thin film portion 24A. For example, the film thickness of thin film portion 24A may be larger than the film thickness of thin film portion 24C.

In the present modification, drain electrode 36 is provided on thin film portion 24C. As a result, the distance between the hetero interface between electron transit layer 22 and electron supply layer 24 and drain electrode 36 is shortened. Therefore, the contact resistance between 2DEG 26 and drain electrode 36 can be reduced. According to nitride semiconductor device 2 of the present modification, the on-resistance can be further reduced.

### Second exemplary embodiment

Then, a second exemplary embodiment will be described.

The second exemplary embodiment is different from the first exemplary embodiment in that the electron supply layer includes a second thick film portion. Hereinafter, differences from the first exemplary embodiment will be mainly described, and description of common points will be omitted or simplified.

### Configuration

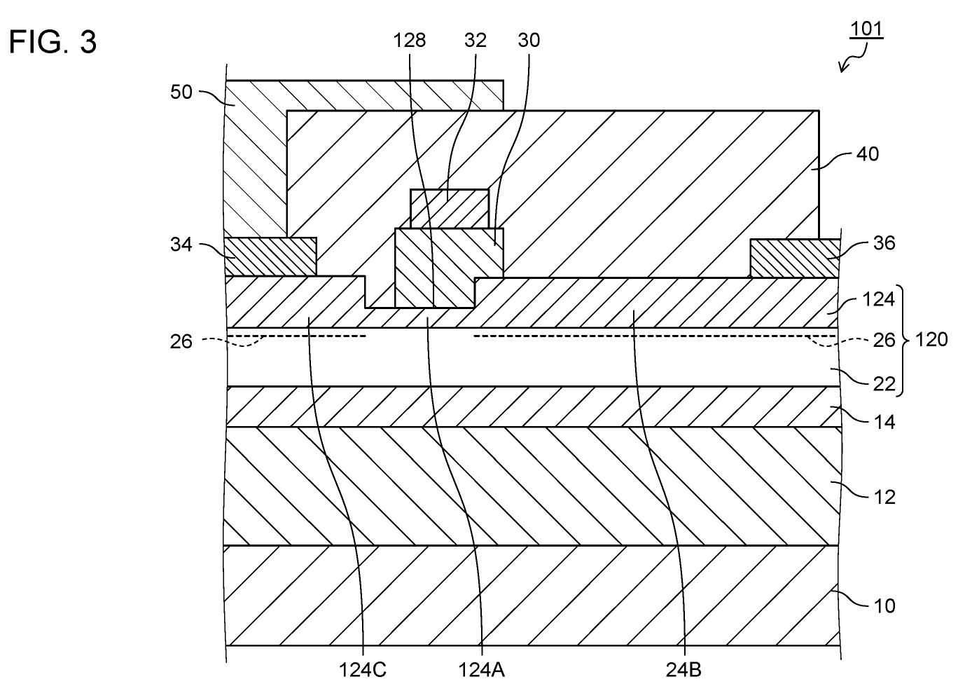

FIG. 3 is a cross-sectional view of nitride semiconductor device 101 according to the present exemplary embodiment. As illustrated in FIG. 3, nitride semiconductor device 101 is different from nitride semiconductor device 1 illustrated in FIG. 1 in that semiconductor laminate 120 is provided instead of semiconductor laminate 20. Semiconductor laminate 120 is different from semiconductor laminate 20 in that electron supply layer 124 is included instead of electron supply layer 24.

Electron supply layer 124 is different in cross-sectional shape from electron supply layer 24. Specifically, electron supply layer 124 includes thin film portion 124A and thick film portions 24B and 124C. In other words, electron supply layer 124 has gate recess 128 which is a recess provided on the upper surface. Thin film portion 124A corresponds to a bottom portion of gate recess 128, and a side wall of each of thick film portions 24B and 124C on the side of thin film portion 124A corresponds to a side wall of gate recess 128.

Thin film portion 124A is an example of a first thin film portion, and is located between gate electrode 32 and source electrode 34 in a plan view of substrate 10. In the present exemplary embodiment, thin film portion 124A is further provided at a location overlapping p-type gate layer 30 in a plan view. Thin film portion 124A does not overlap source electrode 34 in a plan view. Thin film portion 124A is provided with a substantially uniform film thickness continuously from the end of thick film portion 24B to the end of thick film portion 124C in a plan view.

Thick film portion 124C is an example of the second thick film portion, and is located between gate electrode 32 and source electrode 34 in a plan view of substrate 10. In the present exemplary embodiment, thick film portion 124C is further provided at a location overlapping source electrode 34 in a plan view. That is, source electrode 34 is provided on thick film portion 124C. Thick film portion 124C does not overlap p-type gate layer 30 in a plan view. Thick film portion 124C is provided with a substantially uniform film thickness continuously from an end of thin film portion 124A to a location overlapping source electrode 34 in a plan view.

The film thickness of thick film portion 124C may be the same as or different from the film thickness of thick film portion 24B. For example, the film thickness of thick film portion 24B may be larger than the film thickness of thick film portion 124C.

A boundary between thin film portion 124A and thick film portion 124C is located between p-type gate layer 30 and source electrode 34 in a plan view of substrate 10. Thin film portion 124A and thick film portion 124C form a step, and the step is not covered with p-type gate layer 30. The side wall of thick film portion 124C located at the boundary is, for example, perpendicular to the main surface of substrate 10.

### Effects and the like

As described above, in nitride semiconductor device 101 according to the present exemplary embodiment, electron supply layer 124 includes thick film portion 124C. As a result, in the region between p-type gate layer 30 and source electrode 34, the concentration of 2DEG 26 generated in the vicinity of the interface between thick film portion 124C and electron transit layer 22 can be increased. Therefore, the on-resistance of nitride semiconductor device 101 can be reduced.

In addition, nitride semiconductor device 101 can achieve both the reduction of the parasitic capacitance and the improvement of the withstand voltage, similarly to nitride semiconductor device 1 according to the first exemplary embodiment. Hereinafter, the reduction of the parasitic capacitance will be described based on simulation results performed by the present inventors.

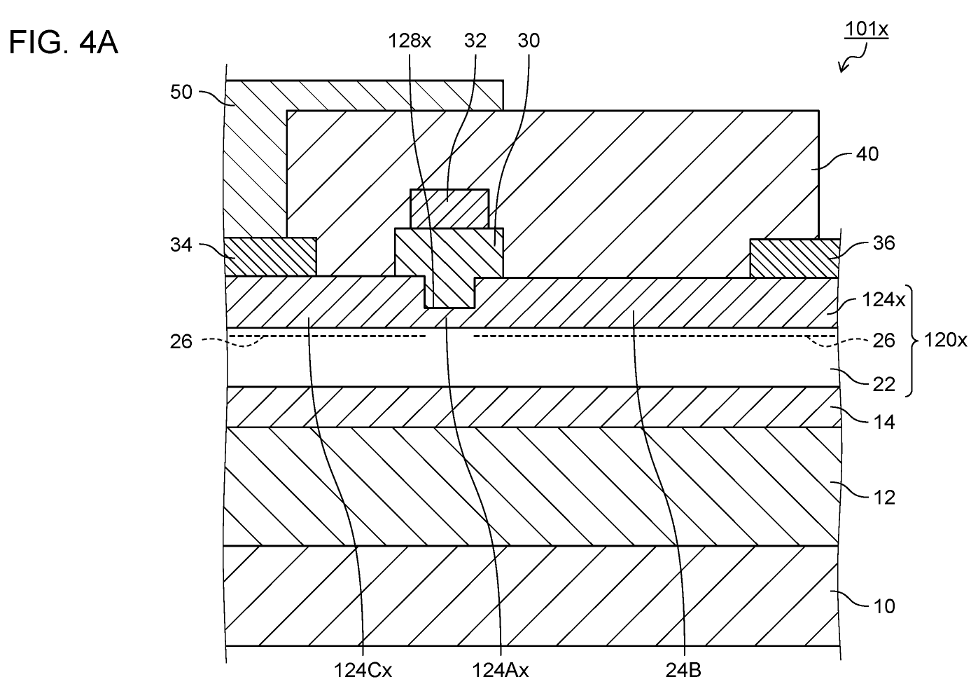

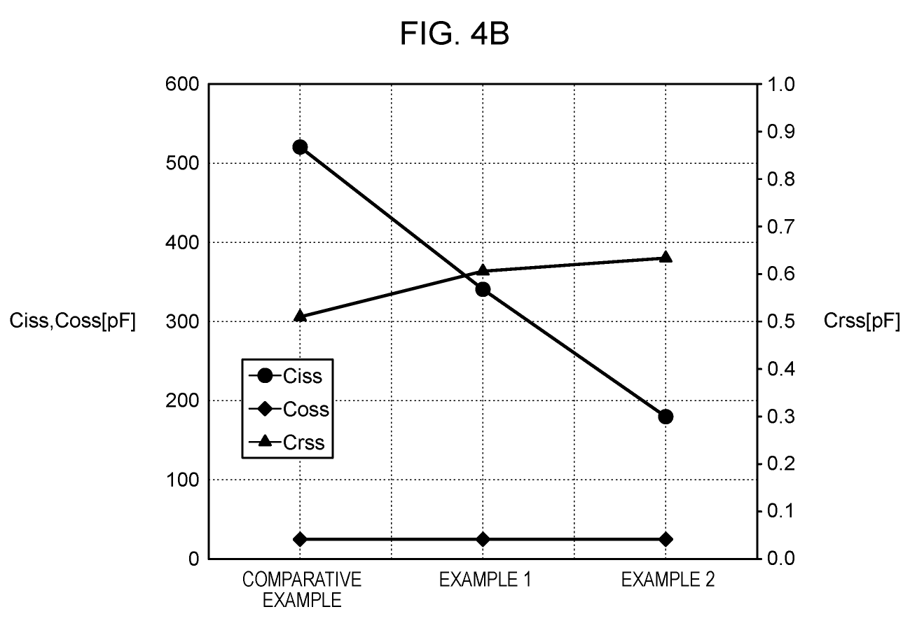

FIG. 4A is a cross-sectional view of nitride semiconductor device 101x according to a comparative example. As shown in FIG. 4A, nitride semiconductor device 101x according to the comparative example is different from nitride semiconductor device 101 shown in FIG. 3 in that semiconductor laminate 120x is provided instead of semiconductor laminate 120. Semiconductor laminate 120x is different from semiconductor laminate 120 in that electron supply layer 124x is included instead of electron supply layer 124. P-type gate layer 30 covers the upper surface of thin film portion 124Ax, a part of the upper surface of thick film portion 24B, and a part of the upper surface of thick film portion 124Cx in contact with each other. That is, p-type gate layer 30 is provided so as to cover the entire bottom surface and side walls of gate recess 128x.

In the comparative example illustrated in FIG. 4A, a portion of p-type gate layer 30 covering thick film portion 24B and a portion covering thick film portion 124Cx face 2DEG 26. This increases the parasitic capacitance generated between gate electrode 32 and 2DEG 26.

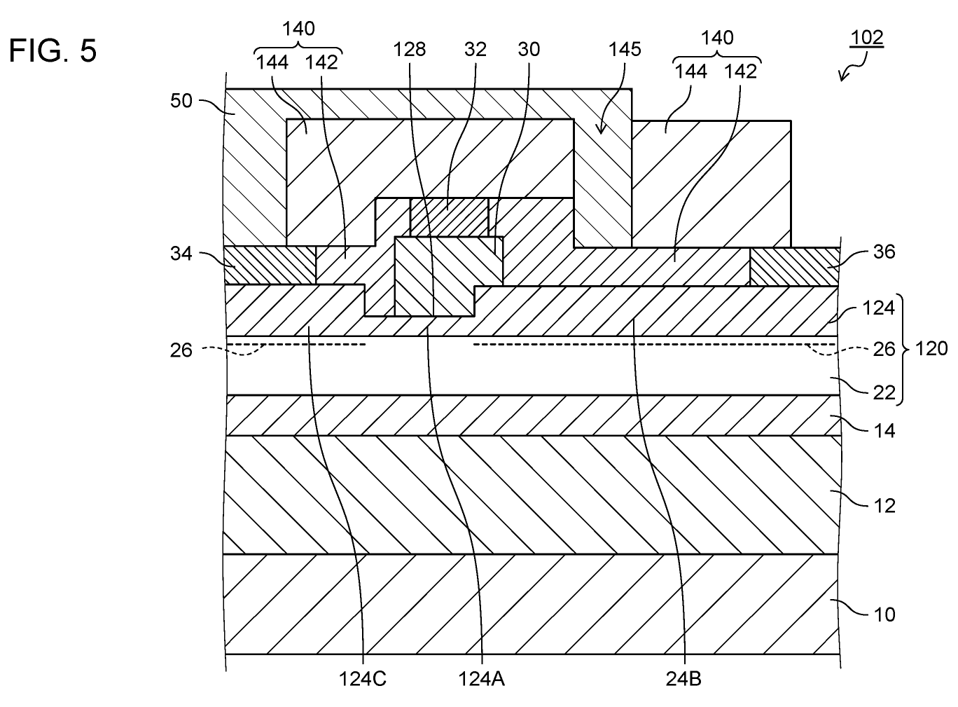

FIG. 4B is a graph showing capacitance characteristics of the nitride semiconductor devices according to the comparative example and the example. The comparative example shown in FIG. 4B has the same configuration as nitride semiconductor device 101x shown in FIG. 4A. Example 1 has the same configuration as nitride semiconductor device 101 shown in FIG. 3. Example 2 has the same configuration as nitride semiconductor device 102 shown in FIG. 5 described later. Example 2 will be described later.

FIG. 4B illustrates the input capacitance Ciss, the output capacitance Coss, and the feedback capacitance Crss of the devices according to the comparative example and each example. The input capacitance Ciss is the sum of the gate-source parasitic capacitance Cgs and the gate-drain parasitic capacitance Cgd. The output capacitance Coss is the sum of the drain-source parasitic capacitance Cds and the gate-drain parasitic capacitance Cgd. The feedback capacitance Crss is a gate-drain parasitic capacitance Cgd.

As illustrated in FIG. 4B, the output capacitance Coss is almost the same in both the comparative example and Example 1. In contrast, the input capacitance Ciss of Example 1 is smaller than input capacitance of the comparative example. On the other hand, the feedback capacitance Crss of the comparative example is smaller than the feedback capacitance of Example 1. However, the input capacitance Ciss has a larger order of capacitance value than the feedback capacitance Crss. That is, it can be seen that the configuration according to Example 1 capable of reducing the input capacitance Ciss has a large parasitic capacitance reduction effect.

In Example 1, that is, nitride semiconductor device 101 according to the second exemplary embodiment, it is considered that the input capacitance Ciss can be greatly reduced because the parasitic capacitance Cgs between p-type gate layer 30 and the 2DEG on source electrode 34 side can be reduced as described above. The same applies to nitride semiconductor device 1 according to the first exemplary embodiment.

### Modifications

Then, a plurality of modifications of the second exemplary embodiment will be described. Hereinafter, differences from the second exemplary embodiment will be mainly described, and description of common points will be omitted or simplified.

### Modification 1

FIG. 5 is a cross-sectional view of nitride semiconductor device 102 according to Modification 1. As illustrated in FIG. 5, nitride semiconductor device 102 is different from nitride semiconductor device 101 illustrated in FIG. 3 in that interlayer insulating layer 140 is provided instead of interlayer insulating layer 40.

Interlayer insulating layer 140 includes SiN layer 142 and SiO₂ layer 144. SiO₂ layer 144 is provided above SiN layer 142. Interlayer insulating layer 140 may further include other insulating layers such as SiON and Al₂O₃.

SiN layer 142 covers in contact with the upper surface of electron supply layer 124 and with the upper surface and side surface of p-type gate layer 30. The film thickness of SiN layer 142 is, for example, between 200 nm and 500 nm. FIG. 5 shows an example in which the film thickness of SiN layer 142 is the same as the film thicknesses of source electrode 34 and drain electrode 36, but the present disclosure is not limited thereto. The film thickness of SiN layer 142 may be smaller or larger than the film thicknesses of source electrode 34 and drain electrode 36. SiN layer 142 is formed by, for example, a plasma CVD method, an ALD method, or the like.

SiO₂ layer 144 covers the upper surface of SiN layer 142 in contact therewith. The film thickness of SiO₂ layer 144 is larger than the film thickness of SiN layer 142. The film thickness of SiO₂ layer 144 is, for example, between 100 nm and 800 nm. The film thickness of SiO₂ layer 144 may be the same as or smaller than the film thickness of SiN layer 142. SiO₂ layer 144 is formed by, for example, a plasma CVD method, an ALD method, or the like, but may be formed by coating.

In addition, in SiO₂ layer 144, through hole 145 is provided between p-type gate layer 30 and drain electrode 36 in a plan view, and a part of source field plate 50 is provided in through hole 145. As a result, the gate-drain parasitic capacitance Cgd can be reduced.

The capacitance characteristic of nitride semiconductor device 102 according to the present modification corresponds to the capacitance characteristic of Example 2 illustrated in FIG. 4B. The feedback capacitance Crss depends on the film thicknesses of SiN layer 142 and SiO₂ layer 144 under source field plate 50, the length of source field plate 50, the gate-drain distance, and the like, and as illustrated in FIG. 4B, the feedback capacitance Crss of Example 2 is higher than feedback capacitance of Example 1. In contrast, SiO₂ layer 144 having a relative dielectric constant lower than the relative dielectric constant of SiN layer 142 is provided, and thus the gate-source parasitic capacitance Cgs can be reduced, and the input capacitance Ciss of Example 2 is lower than input capacitance of Example 1. It can be seen that the increase in the feedback capacitance Crss is only slight, and the configuration according to Example 2 capable of reducing the input capacitance Ciss has a large parasitic capacitance reduction effect.

As described above, according to nitride semiconductor device 102 of the present modification, the input capacitance Ciss can be further reduced.

### Modification 2

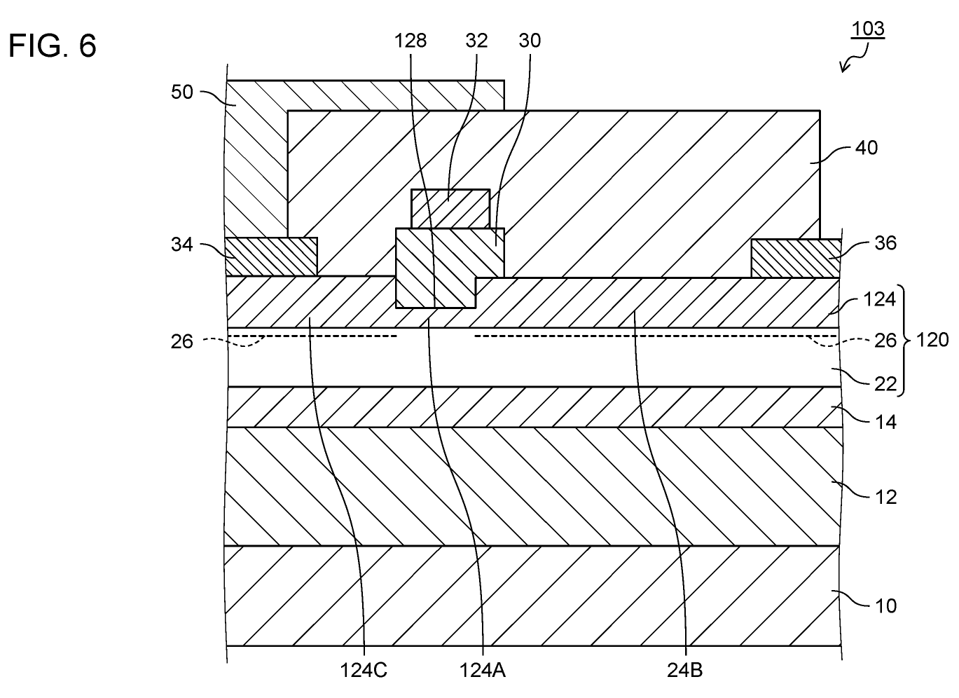

FIG. 6 is a cross-sectional view of nitride semiconductor device 103 according to Modification 2. As illustrated in FIG. 6, nitride semiconductor device 103 differs from nitride semiconductor device 101 illustrated in FIG. 3 in a location relationship between gate recess 128 and p-type gate layer 30.

In the present modification, p-type gate layer 30 is provided so as to fill gate recess 128. Specifically, an end of p-type gate layer 30 on the side of source electrode 34 and an end of gate recess 128 on the side of source electrode 34 coincide with each other in a plan view of substrate 10. P-type gate layer 30 continuously covers the upper surface of thin film portion 124A from the side wall of thick film portion 124C to the side wall of thick film portion 24B. P-type gate layer 30 is in contact with the side wall of each of thick film portion 24B and thick film portion 124C. P-type gate layer 30 covers a part of the upper surface of thick film portion 24B but does not cover the upper surface of thick film portion 124C.

As a result, the range in which the concentration of 2DEG 26 is high between the gate and the source can be increased, and the on-resistance can be reduced. In addition, in the present modification, the end of p-type gate layer 30 on source electrode 34 side is located on thin film portion 124A, and thus the parasitic capacitance can be reduced. In addition, p-type gate layer 30 extends across thin film portion 124A and thick film portion 24B, and thus it is possible to alleviate the electric field concentration and increase the withstand voltage.

Nitride semiconductor device 103 according to the present modification may include interlayer insulating layer 140 instead of interlayer insulating layer 40, similarly to nitride semiconductor device 102 according to Modification 1.

### Modification 3

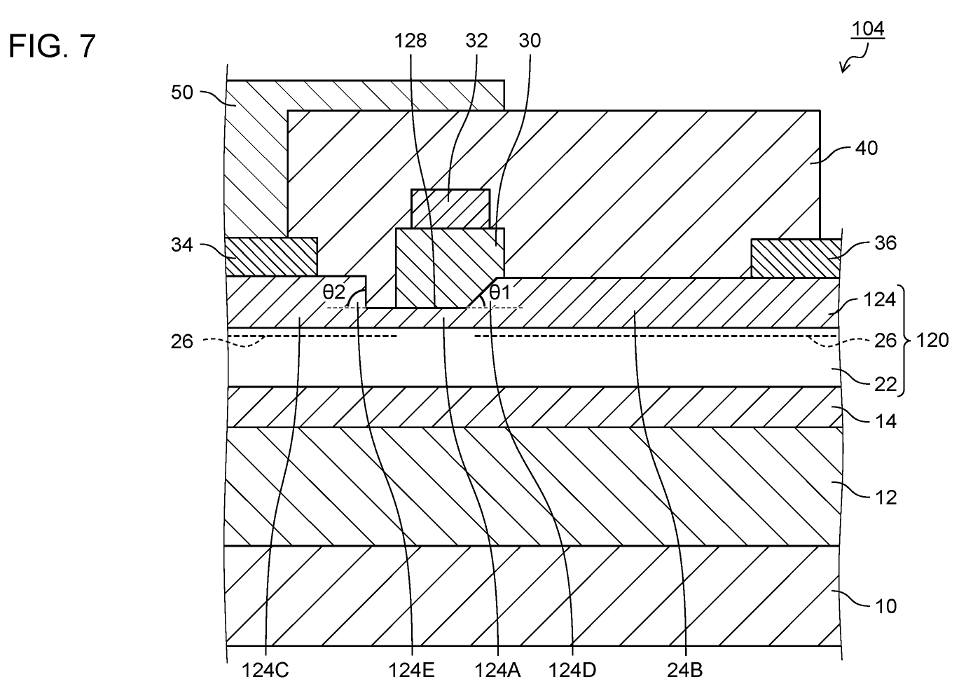

FIG. 7 is a cross-sectional view of nitride semiconductor device 104 according to Modification 3. As illustrated in FIG. 7, nitride semiconductor device 104 is different from nitride semiconductor device 101 illustrated in FIG. 3 in the cross-sectional shape of electron supply layer 124.

In the present modification, as illustrated in FIG. 7, electron supply layer 124 includes thin film portion 124A, thick film portions 24B and 124C, and inclined portions 124D and 124E.

Inclined portion 124D is an example of a first inclined portion with the upper surface inclined, and is located between thin film portion 124A and thick film portion 24B in a plan view of substrate 10. The upper surface of inclined portion 124D is a plane inclined at inclination angle θ1. Inclination angle θ1 is an angle on thick film portion 24B side among angles formed by the upper surface of inclined portion 124D and a surface parallel to the main surface of substrate 10. Inclination angle θ1 is, for example, between 20° and 80°.

Inclined portion 124E is an example of a second inclined portion with the upper surface inclined, and is located between thin film portion 124A and thick film portion 124C in a plan view of substrate 10. The upper surface of inclined portion 124E is a plane inclined at inclination angle θ2. Inclination angle θ2 is an angle on thick film portion 124C side among angles formed by the upper surface of inclined portion 124E and a surface parallel to the main surface of substrate 10. Inclination angle θ2 is larger than inclination angle θ1. Inclination angle θ2 is, for example, between 30° and 90°. The case where inclination angle θ2 is 90° is substantially synonymous with the case where inclined portion 124E is not provided.

Inclined portions 124D and 124E are formed by adjusting the end shape of the opening of the resist mask during dry etching for forming gate recess 128. Specifically, in the resist mask, an opening is provided in a region corresponding to gate recess 128, and an inclined surface is provided at an end of the opening. In this case, the end on drain electrode 36 side, that is, the inclined surface of the portion corresponding to inclined portion 124D is made gentler than the end on source electrode 34 side, that is, the inclined surface of the portion corresponding to inclined portion 124E. As a result, each inclined surface formed at the end of the opening is transferred to electron supply layer 124 by dry etching, and inclined portions 124D and 124E are formed. The inclination of the upper surface of inclined portion 124D is gentler than the inclination of the upper surface of inclined portion 124E.

The inclination can be changed by adjusting the baking temperature of the resist mask. For example, the inclination becomes gentle by baking at a high temperature, and the inclination can be made steep or perpendicular by baking at a low temperature. The baking temperature of the resist mask is not particularly limited, and is, for example, between 80°C and 160°C. In addition, making the distance between the gate and the drain longer than the distance between the gate and the source allows the inclination of the end corresponding to inclined portion 124D to be made gentler than the inclination of the end corresponding to inclined portion 124E.

In the present modification, p-type gate layer 30 continuously covers the upper surface of inclined portion 124D from thin film portion 124A to thick film portion 24B in contact therewith. As a result, the electric field caused by the high drain voltage is easily dispersed not only in the end of thin film portion 124A on drain electrode 36 side and the end of p-type gate layer 30 on drain electrode 36 side but also in the upper surface of inclined portion 124D. Therefore, it is possible to alleviate the electric field concentration and increase the withstand voltage.

Nitride semiconductor device 104 according to the present modification may include interlayer insulating layer 140 instead of interlayer insulating layer 40, similarly to nitride semiconductor device 102 according to Modification 1. In nitride semiconductor device 104, similarly to nitride semiconductor device 103 according to Modification 2, p-type gate layer 30 may be provided so as to fill gate recess 128. Specifically, p-type gate layer 30 may be in contact with the upper surface of inclined portion 124E.

### Modification 4

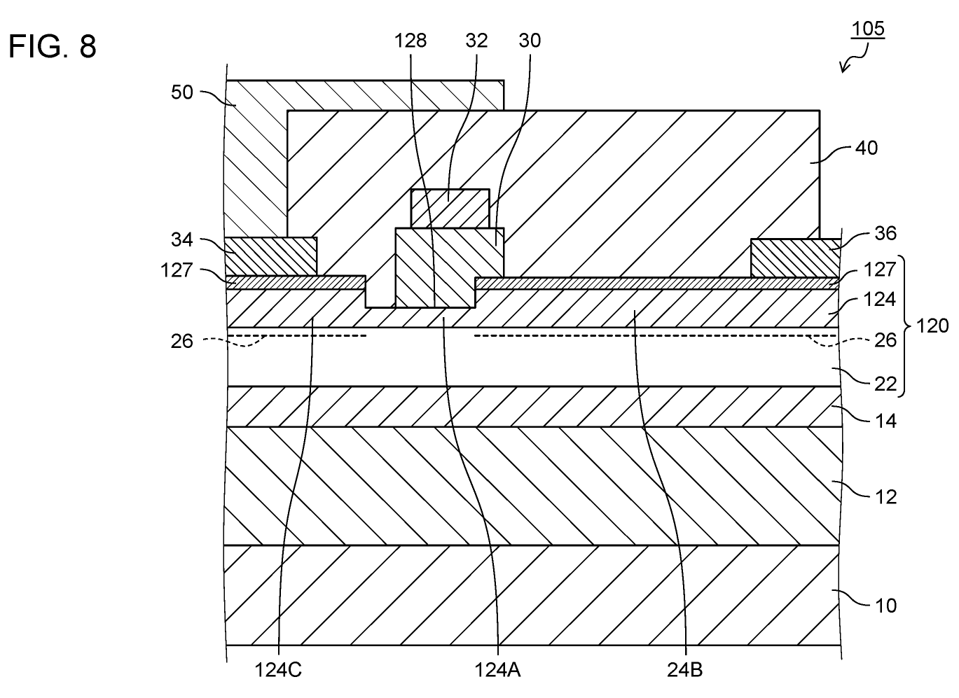

FIG. 8 is a cross-sectional view of nitride semiconductor device 105 according to Modification 4. As shown in FIG. 8, nitride semiconductor device 105 differs from nitride semiconductor device 101 shown in FIG. 3 in a laminated structure of semiconductor laminate 120.

As illustrated in FIG. 8, semiconductor laminate 120 further includes electron supply layer 127. Electron supply layer 127 corresponds to a second electron supply layer in a case where electron supply layer 124 is a first electron supply layer. Electron supply layer 127 is provided in contact with the upper surface of electron supply layer 124. Specifically, electron supply layer 127 is provided in contact with the upper surface of each of thick film portion 24B and thick film portion 124C, and is not provided on the upper surface of thin film portion 124A. That is, electron supply layer 127 is not provided in gate recess 128.

Electron supply layer 127 is, for example, a layer consisting of InAlGaN. The layer consisting of InAlGaN is also called a cap layer. The laminated structure of electron supply layer 127 and electron supply layer 124 allows the polarization amount of the piezoelectric polarization to be increased, and the concentration of 2DEG 26 to be increased. This can reduce the on-resistance. The thickness of electron supply layer 127 is, for example, between 20 nm and 80 nm.

Electron supply layer 127 may be, for example, an oxide layer containing gallium oxide as a main component. The gallium oxide is, for example, κ-Ga₂O₃ and has a band gap of about 4.9eV. For example, when electron supply layer 124 is Al_{0.2}Ga_{0.8}N, the band gap of electron supply layer 127 is larger than the band gap of electron supply layer 124, and the polarization is also larger. In this case, 2DEG is also generated in the vicinity of the interface between electron supply layer 127 and electron supply layer 124. That is, nitride semiconductor device 105 is a device having a multi-channel including 2DEG generated in two layers. Therefore, the on-resistance can be further reduced.

Gallium oxide has a refractive index of less than 2.0 at a wavelength of 365 nm, which is smaller than a refractive index of 2.7 of GaN. Therefore, there is an effect of confining light in electron supply layer 127. The utilization efficiency of light generated at the interface between p-type gate layer 30 and electron supply layer 124 is increased, and the carrier concentration of 2DEG 26 can be increased. Therefore, the effect of reducing the on-resistance can be further enhanced.

Nitride semiconductor device 105 according to the present modification may include interlayer insulating layer 140 instead of interlayer insulating layer 40, similarly to nitride semiconductor device 102 according to Modification 1. In nitride semiconductor device 105, similarly to nitride semiconductor device 103 according to Modification 2, p-type gate layer 30 may be provided so as to fill gate recess 128. In addition, in nitride semiconductor device 105, similarly to nitride semiconductor device 104 according to Modification 3, electron supply layer 124 may include inclined portions 124D and 124E. In this case, the end of electron supply layer 127 on gate recess 128 side may also be provided with an inclined portion with the upper surface inclined so as to be continuous from each of inclined portions 124D and 124E.

### Modification 5

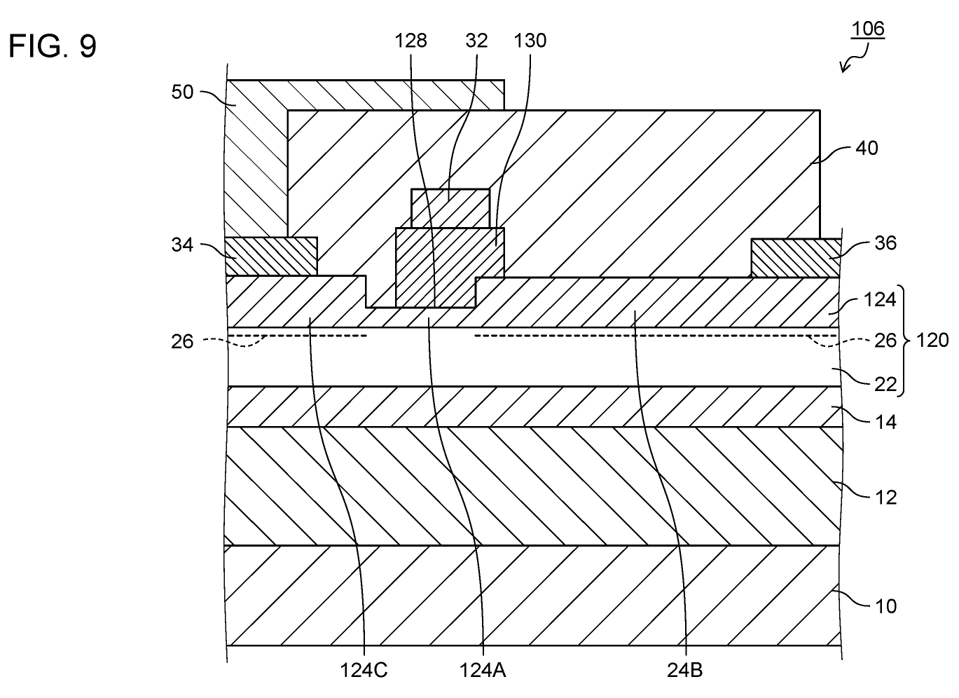

FIG. 9 is a cross-sectional view of nitride semiconductor device 106 according to Modification 5. As illustrated in FIG. 9, nitride semiconductor device 106 is different from nitride semiconductor device 101 illustrated in FIG. 3 in that oxide layer 130 is provided instead of p-type gate layer 30.

Oxide layer 130 is an example of a threshold adjustment layer, and is an oxide layer provided between source electrode 34 and drain electrode 36. Oxide layer 130 is a layer containing, for example, gallium oxide (Ga₂O₃) or nickel oxide (NiO) as a main component. The film thickness of oxide layer 130 is, for example, between 50 nm and 200 nm.

Similarly to p-type gate layer 30, oxide layer 130 containing Ga₂O₃ or NiO as a main component can raise the potential of the conduction band edge of the channel. Therefore, the carrier concentration in the direction immediately below oxide layer 130 can be reduced, and the threshold value of the transistor can be shifted to the positive side. Therefore, nitride semiconductor device 106 can be operated normally off.

Oxide layer 130 may be a layer consisting of SiO₂, Al₂O₃, or the like. Nitride semiconductor device 106 according to the present modification can be operated as a so-called metal oxide semiconductor FET (MOSFET). Alternatively, nitride semiconductor device 106 may include an insulating layer such as SiN or SiON instead of oxide layer 130. Nitride semiconductor device 106 can be operated as a metal insulator semiconductor FET (MISFET).

In addition, nitride semiconductor device 106 according to the present modification may include interlayer insulating layer 140 instead of interlayer insulating layer 40, similarly to nitride semiconductor device 102 according to Modification 1. In nitride semiconductor device 106, similarly to nitride semiconductor device 103 according to Modification 2, oxide layer 130 may be provided so as to fill gate recess 128. In addition, in nitride semiconductor device 106, similarly to nitride semiconductor device 104 according to Modification 3, electron supply layer 124 may include inclined portions 124D and 124E. In nitride semiconductor device 106, similarly to nitride semiconductor device 105 according to Modification 4, semiconductor laminate 120 may include electron supply layer 127.

### Plan layout

Subsequently, a plan layout of nitride semiconductor device 101 according to the second exemplary embodiment will be described. The plan layouts of nitride semiconductor devices 102 to 106 according to Modifications 1 to 5 are substantially the same.

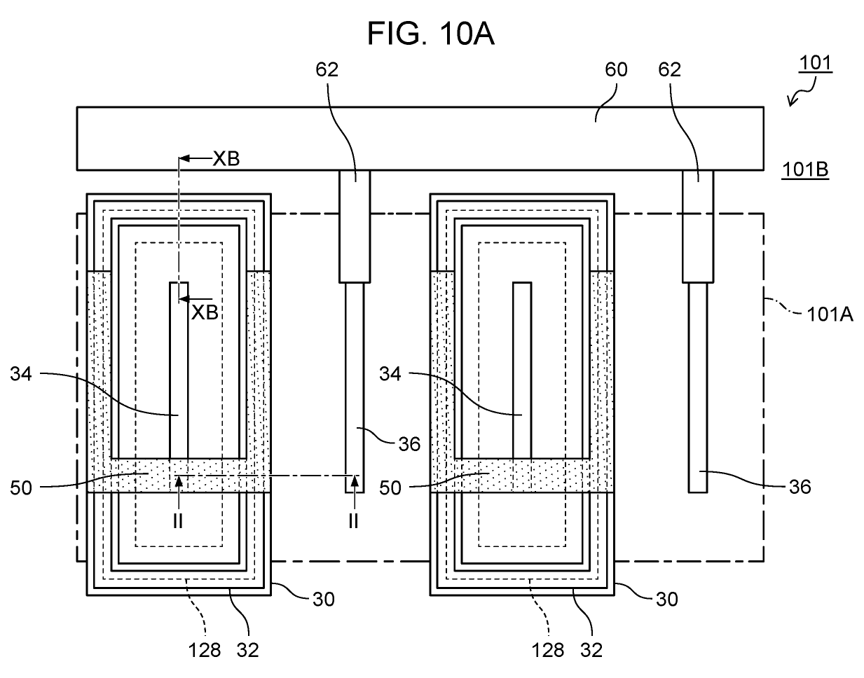

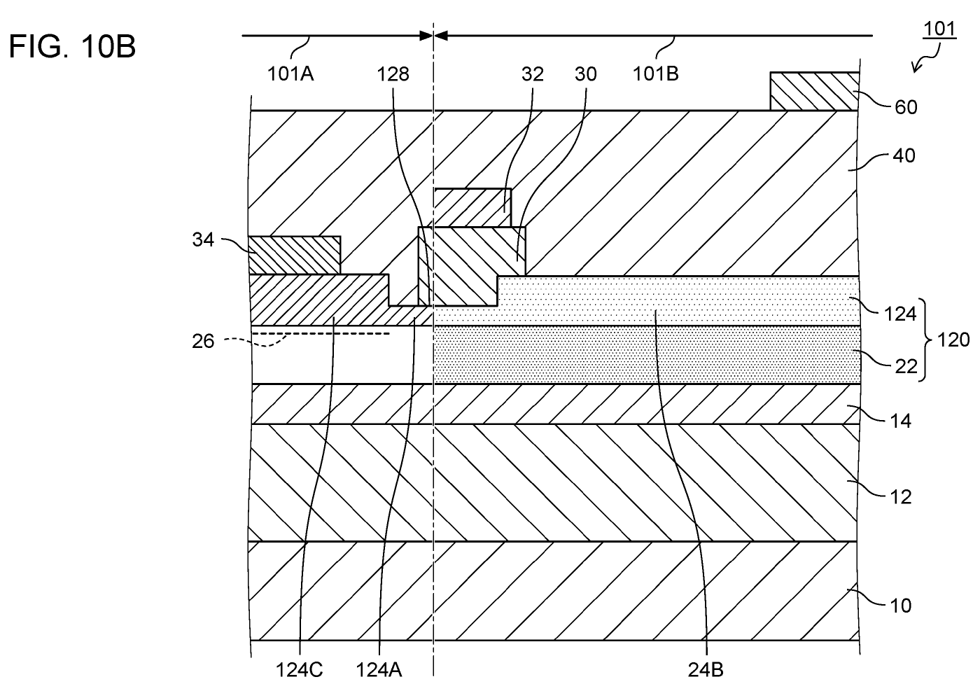

FIG. 10A is a plan view of nitride semiconductor device 101 according to the present exemplary embodiment. FIG. 10B is a cross-sectional view of nitride semiconductor device 101 taken along line XB-XB in FIG. 10A. In addition, a cross section of nitride semiconductor device 101 taken along line II-II shown in FIG. 10A is as shown in FIG. 3.

As illustrated in FIG. 10A, nitride semiconductor device 101 can be divided into active region 101A and inactive region 101B in a plan view.

Active region 101A is a region within a range surrounded by a rectangular alternate long and short dash line illustrated in FIG. 10A. The active region 101A is a main operation region of nitride semiconductor device 101. Specifically, active region 101A is a region that becomes a main current path when nitride semiconductor device 101 is turned on. Active region 101A may be referred to as a device region. Active region 101A is provided with gate electrode 32, source electrode 34, drain electrode 36, source field plate 50, and gate recess 128. In FIG. 10A, dot shading is applied to source field plate 50 to distinguish it from others.

Source electrode 34 and drain electrode 36 both have, for example, an elongated shape in one direction, and are disposed such that longitudinal directions thereof are parallel to each other. The plurality of source electrodes 34 and the plurality of drain electrodes 36 are alternately disposed one by one with gate electrode 32 and p-type gate layer 30 interposed therebetween. Gate electrode 32, p-type gate layer 30, and gate recess 128 are annularly provided so as to surround one source electrode 34. In active region 101A, as illustrated in FIGS. 3 and 10B, 2DEG 26 is generated in the vicinity of the interface between electron transit layer 22 and electron supply layer 124.

Inactive region 101B is a region other than active region 101A. Inactive region 101B is provided around active region 101A, and may also be referred to as a peripheral region or an element isolation region. In inactive region 101B, at least electron transit layer 22 can be regarded as a region in which resistance is increased such that 2DEG 26 is not generated. The resistance is increased by, for example, ion implantation of Fe or boron B. In FIG. 10B, a region in which resistance is increased by ion implantation is indicated by dot shading. For example, the ion implantation is performed on electron transit layer 22 and electron supply layer 24, but the present disclosure is not limited thereto. The ion implantation may be performed only in a region where 2DEG 26 of electron transit layer 22 can occur, or the ion implantation may also be performed in buffer layer 12, back barrier layer 14, and electron supply layer 24.

In the present exemplary embodiment, as illustrated in FIG. 10A, drain pad 60 is provided in inactive region 101B. Drain pad 60 is provided at one end in the longitudinal direction of source electrode 34. Drain pad 60 is electrically connected to drain electrode 36 via drain wiring 62. Drain wiring 62 is provided so as to extend across inactive region 101B and active region 101A, and is connected to drain electrode 36 provided in active region 101A. As illustrated in FIG. 10B, drain pad 60 is provided on the upper surface of interlayer insulating layer 40. Drain wiring 62 is connected to drain electrode 36 via a via hole or the like provided in interlayer insulating layer 40.

Drain pad 60 and drain wiring 62 are both formed using a metal material. As the metal material that can be used for the pad and the wiring, a metal having a low resistivity and a high thermal conductivity such as Au or Cu can be used. The pad and the wiring are single-layer metal films consisting of a single metal or an alloy of two or more metals, but may be laminated films of a plurality of metal films having different compositions.

Although not illustrated in FIG. 10A, inactive region 101B may be provided with a gate pad and a gate wiring electrically connected to gate electrode 32, a source pad and a source wiring electrically connected to source electrode 34, and the like. Inactive region 101B may be referred to as a pad area.

In the present exemplary embodiment, as illustrated in FIGS. 10A and 10B, gate electrode 32, p-type gate layer 30, gate recess 128, and thin film portion 124A and thick film portion 24B of electron supply layer 124 are further located between source electrode 34 and drain pad 60 in a plan view of substrate 10. P-type gate layer 30 extends across thin film portion 124A and thick film portion 24B between source electrode 34 and drain pad 60. A part of the boundary between active region 101A and inactive region 101B coincides with a part of the contour on the inner peripheral side of gate electrode 32 in a plan view. Both gate recess 128 and p-type gate layer 30 are provided across the boundary between active region 101A and inactive region 101B. This makes it possible to suppress an increase in so-called buffer leakage. The location of the boundary between active region 101A and inactive region 101B may be a location overlapping p-type gate layer 30 in a plan view. For example, the boundary between active region 101A and inactive region 101B may coincide with the boundary between thin film portion 124A and thick film portion 24B.

As a result, the electric field caused by the high drain voltage applied to drain pad 60 can be dispersed, and thus the withstand voltage can be further increased. That is, not only the electric field generated in active region 101A but also the electric field generated between active region 101A and inactive region 101B can be dispersed, and the withstand voltage can be further enhanced.

In the example of FIG. 10A, gate electrode 32 and p-type gate layer 30 surround source electrode 34 in a plan view, but the present disclosure is not limited to this. Gate electrode 32 and p-type gate layer 30 may be provided in a rectangular shape provided in parallel with source electrode 34 and drain electrode 36, respectively. For example, gate electrode 32 may be a so-called finger electrode. In this case, although gate recess 128 and p-type gate layer 30 located below finger electrode are provided so as to extend across the boundary between thin film portion 124A and thick film portion 24B at the boundary between active region 101A and inactive region 101B close to drain pad 60, p-type gate layer 30 may not extend across thin film portion 124A and thick film portion 24B between drain pad 60 and source electrode 34.

### Third exemplary embodiment

Then, a third exemplary embodiment will be described.

The third exemplary embodiment is different from the first and second exemplary embodiments in that a nitride semiconductor device includes two electrodes instead of a source electrode and a drain electrode, and is a bidirectional device capable of bidirectionally flowing a current between the two electrodes. Hereinafter, differences from the first and second exemplary embodiments will be mainly described, and description of common points will be omitted or simplified.

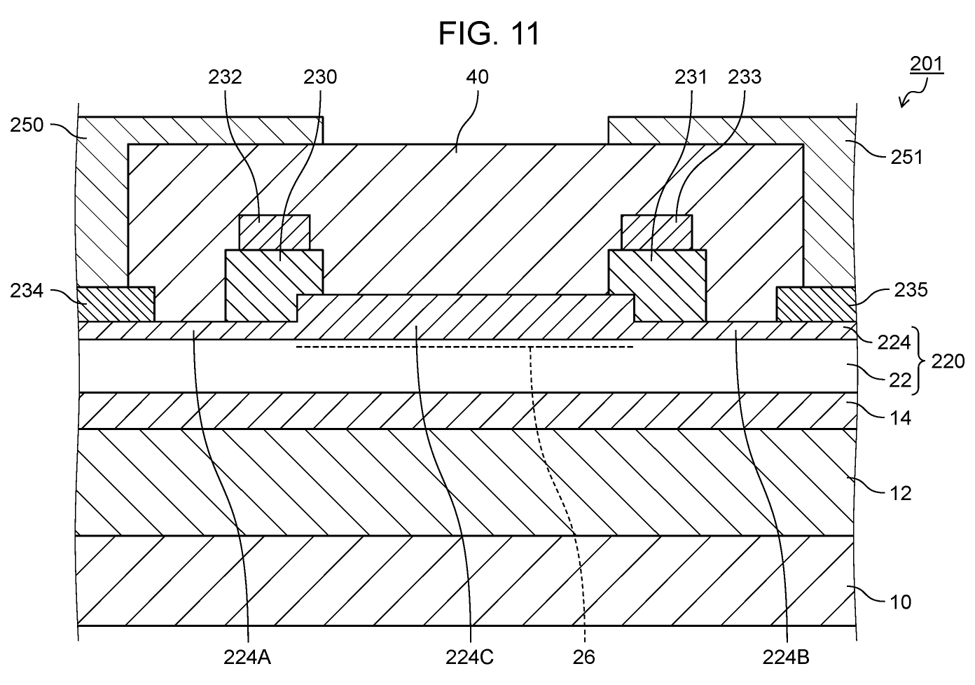

FIG. 11 is a cross-sectional view of nitride semiconductor device 201 according to the present exemplary embodiment. As illustrated in FIG. 11, nitride semiconductor device 201 includes substrate 10, buffer layer 12, back barrier layer 14, semiconductor laminate 220, p-type gate layers 230 and 231, gate electrodes 232 and 233, first electrode 234, second electrode 235, interlayer insulating layer 40, first field plate 250, and second field plate 251.

Semiconductor laminate 220 includes electron transit layer 22 and electron supply layer 224. Electron supply layer 224 is different in cross-sectional shape from electron supply layer 124. Specifically, electron supply layer 224 includes thin film portions 224A and 224B and thick film portion 224C.

Thin film portion 224A is an example of a first thin film portion, and is located between gate electrode 232 and first electrode 234 in a plan view of substrate 10. In the present exemplary embodiment, thin film portion 224A is further provided at a location overlapping p-type gate layer 230 and a location overlapping first electrode 234 in a plan view. Thin film portion 224A is provided with a substantially uniform film thickness continuously from a location overlapping p-type gate layer 230 to a location overlapping first electrode 234.

Thin film portion 224B is an example of the second thin film portion, and is located between gate electrode 233 and second electrode 235 in a plan view of substrate 10. In the present exemplary embodiment, thin film portion 224B is further provided at a location overlapping p-type gate layer 231 and a location overlapping second electrode 235 in a plan view. Thin film portion 224B is provided with a substantially uniform film thickness continuously from a location overlapping p-type gate layer 231 to a location overlapping second electrode 235.

Thick film portion 224C is an example of the first thick film portion, and is located between thin film portion 224A and thin film portion 224B in a plan view of substrate 10. In the present exemplary embodiment, thick film portion 224C is further provided at a location overlapping p-type gate layer 230 and a location overlapping p-type gate layer 231 in a plan view. Thick film portion 224C is provided with a substantially uniform film thickness continuously from a location overlapping p-type gate layer 230 to a location overlapping p-type gate layer 231.

The film thicknesses of thin film portions 224A and 224B are, for example, the same as the film thickness of thin film portion 24A according to the first exemplary embodiment. In addition, the film thickness of thick film portion 224C is, for example, the same as the film thickness of thick film portion 24B according to the first exemplary embodiment. The film thickness of thin film portion 224A and the film thickness of thin film portion 224B may be equal to or different from each other.

A boundary between thin film portion 224A and thick film portion 224C overlaps p-type gate layer 230 in a plan view of substrate 10. Thin film portion 224A and thick film portion 224C form a step, and p-type gate layer 230 is provided so as to cover the step. The side wall of thick film portion 224C located at the boundary is, for example, perpendicular to the main surface of substrate 10.

A boundary between thin film portion 224B and thick film portion 224C overlaps p-type gate layer 231 in a plan view of substrate 10. Thin film portion 224B and thick film portion 224C form a step, and p-type gate layer 231 is provided so as to cover the step. The side wall of thick film portion 224C located at the boundary is, for example, perpendicular to the main surface of substrate 10.

P-type gate layer 230 is an example of a first threshold adjustment layer, and is a p-type nitride semiconductor layer provided between first electrode 234 and second electrode 235. P-type gate layer 230 extends over thin film portion 224A and thick film portion 224C in a plan view of substrate 10. Specifically, p-type gate layer 230 continuously covers the upper surface of thin film portion 224A, the side wall of thick film portion 224C located at the boundary between thin film portion 224A and thick film portion 224C, and the upper surface of thick film portion 224C. In addition, the end of p-type gate layer 230 on first electrode 234 side is located on thin film portion 224A. Thin film portion 224A is provided between the electrode of p-type gate layer 230 on first electrode 234 side and first electrode 234. An end of p-type gate layer 230 on second electrode 235 side is located on thick film portion 224C. P-type gate layer 230 is disposed apart from each of gate electrode 233, first electrode 234, and second electrode 235, and is electrically separated. The upper surface of p-type gate layer 230 is a flat surface, but a step corresponding to the step between thin film portion 224A and thick film portion 224C may be provided.

P-type gate layer 231 is an example of a second threshold adjustment layer, and is a p-type nitride semiconductor layer provided between first electrode 234 and second electrode 235. P-type gate layer 231 extends across thin film portion 224B and thick film portion 224C in a plan view of substrate 10. Specifically, p-type gate layer 231 continuously covers the upper surface of thin film portion 224B, the side wall of thick film portion 224C located at the boundary between thin film portion 224B and thick film portion 224C, and the upper surface of thick film portion 224C. In addition, the end of p-type gate layer 231 on second electrode 235 side is located on thin film portion 224B. Thin film portion 224B is provided between the end of p-type gate layer 231 on second electrode 235 side and second electrode 235. An end of p-type gate layer 231 on first electrode 234 side is located on thick film portion 224C. P-type gate layer 231 is disposed apart from each of gate electrode 232, first electrode 234, and second electrode 235, and is electrically separated. The upper surface of p-type gate layer 231 is a flat surface, but a step corresponding to the step between thin film portion 224B and thick film portion 224C may be provided.

Each of p-type gate layers 230 and 231 is, for example, a film consisting of p-type GaN having a thickness of 200 nm and a carrier concentration of 5 × 10¹⁷ cm⁻³. The thicknesses and carrier concentrations of p-type gate layers 230 and 231 are merely examples, and can be changed as appropriate. P-type gate layers 230 and 231 may be films consisting of p-type AlGaN. P-type gate layers 230 and 231 have the same configuration, but may have different shapes and compositions.

Gate electrode 232 is an example of a first gate electrode, and is provided above p-type gate layer 230. Gate electrode 232 is electrically connected to p-type gate layer 230. Specifically, gate electrode 232 is provided in contact with the upper surface of p-type gate layer 230. In the present exemplary embodiment, gate electrode 232 extends across thin film portion 224A and thick film portion 224C in a plan view of substrate 10. An end of gate electrode 232 on first electrode 234 side overlaps thin film portion 224A in a plan view, and an end of gate electrode 232 on second electrode 235 side overlaps thick film portion 224C in a plan view.

Gate electrode 233 is an example of a second gate electrode, and is provided above p-type gate layer 231. Gate electrode 233 is electrically connected to p-type gate layer 231. Specifically, gate electrode 233 is provided in contact with the upper surface of p-type gate layer 231. In the present exemplary embodiment, gate electrode 233 extends across thin film portion 224B and thick film portion 224C in a plan view of substrate 10. An end of gate electrode 233 on second electrode 235 side overlaps thin film portion 224B in a plan view, and an end of gate electrode 233 on first electrode 234 side overlaps thick film portion 224C in a plan view.

Gate electrodes 232 and 233 are formed using, for example, a conductive material such as metal. For example, gate electrodes 232 and 233 may be made of a material that is in ohmic contact with a p-type nitride semiconductor layer such as p-type GaN, but are not limited thereto, and a material that is in Schottky contact with a p-type nitride semiconductor layer such as p-type GaN may be used. For example, Pd, a Ni-based material, WSi, Au, or the like can be used.

First electrode 234 and second electrode 235 are provided in contact with semiconductor laminate 220 above substrate 10. First electrode 234 and second electrode 235 are provided so as to sandwich p-type gate layers 230 and 231 and gate electrodes 232 and 233 therebetween. Specifically, first electrode 234 is electrically connected to electron transit layer 22 and provided away from p-type gate layer 230 and gate electrode 232. First electrode 234 is provided on thin film portion 224A. Second electrode 235 is electrically connected to electron transit layer 22 and provided away from p-type gate layer 231 and gate electrode 233. Second electrode 235 is provided on thin film portion 224B.

Each of first electrode 234 and second electrode 235 is formed using a conductive material such as metal. As a material of each of first electrode 234 and second electrode 235, for example, a material that is ohmic-connected to an n-type nitride semiconductor layer such as n-type GaN by heat treatment, such as Ti/Al (laminated structure of Ti layer and Al layer), can be used. First electrode 234 and second electrode 235 are formed in the same step using the same material, for example.

At least one of first electrode 234 and second electrode 235 may be provided so as to be in contact with electron transit layer 22. Specifically, two openings penetrating electron supply layer 224 to expose electron transit layer 22 may be provided. In the two openings, first electrode 234 and second electrode 235 are provided so as to cover the inner surfaces thereof, respectively. First electrode 234 and second electrode 235 are each in contact with 2DEG 26 exposed on the inner surface of the corresponding opening. As a result, the contact resistance can be reduced, and thus the on-resistance can be reduced.

First field plate 250 is provided above interlayer insulating layer 40, and is connected to first electrode 234 via an opening provided in interlayer insulating layer 40. First field plate 250 overlaps gate electrode 232 in a plan view of substrate 10. First field plate 250 extends from a location overlapping first electrode 234 in a plan view of substrate 10 to second electrode 235 side beyond gate electrode 232.

Second field plate 251 is provided above interlayer insulating layer 40, and is connected to second electrode 235 via an opening provided in interlayer insulating layer 40. Second field plate 251 overlaps gate electrode 233 in a plan view of substrate 10. Second field plate 251 extends from a location overlapping second electrode 235 in a plan view of substrate 10 to first electrode 234 side beyond gate electrode 233.

First field plate 250 and second field plate 251 are formed using a conductive material such as metal. For example, first field plate 250 and second field plate 251 are plated films consisting of Au, for example. First field plate 250 and second field plate 251 are electrically separated.

First field plate 250 also functions as wiring that electrically connects the first pad (not illustrated) and first electrode 234. Second field plate 251 also functions as wiring that electrically connects the second pad (not illustrated) and second electrode 235. Although not illustrated in FIG. 11, a first gate line and a first gate pad electrically connected to gate electrode 232, a second gate line and a second gate pad electrically connected to gate electrode 233, and the like may be provided above interlayer insulating layer 40.

In nitride semiconductor device 201 according to the present exemplary embodiment, different potentials can be set for gate electrode 232 and gate electrode 233. Nitride semiconductor device 201 is a four-terminal drive device in which potentials can be set independently for four electrodes of gate electrode 232, gate electrode 233, first electrode 234, and second electrode 235. Adjusting the potentials set to the four electrodes of gate electrode 232, gate electrode 233, first electrode 234, and second electrode 235 allows nitride semiconductor device 201 to be operated as a bidirectional device such as a bidirectional switch. Nitride semiconductor device 201 can also function as a diode.

The method for producing nitride semiconductor device 201 according to the present exemplary embodiment is similar to the method for producing nitride semiconductor device 1 according to the first exemplary embodiment. In the method for producing nitride semiconductor device 1, in the step of forming p-type gate layer 30 and gate electrode 32, p-type gate layers 230 and 231 and gate electrodes 232 and 233 can be formed by changing the mask shape for etching.

### Effects and the like

As described above, in nitride semiconductor device 201 according to the present exemplary embodiment, electron supply layer 224 includes thin film portions 224A and 224B and thick film portion 224C. As a result, the concentration of 2DEG 26 generated in the vicinity of the interface between thick film portion 224C and electron transit layer 22 can be increased, and thus the on-resistance can be reduced. On the other hand, it is possible to suppress the occurrence of 2DEG in the vicinity of the interface between each of thin film portions 224A and 224B and electron transit layer 22. For example, when nitride semiconductor device 201 is off, 2DEG can be prevented from being generated in the vicinity of the interface between each of thin film portions 224A and 224B and electron transit layer 22, or the concentration can be sufficiently lowered. As a result, it is possible to reduce the parasitic capacitance generated between gate electrode 232 and first electrode 234 and the parasitic capacitance generated between gate electrode 233 and second electrode 235 during OFF.

In addition, p-type gate layer 230 extends across thin film portion 224A and thick film portion 224C, and thus when a high voltage is applied to second electrode 235 during OFF, the electric field caused by the voltage is dispersed to the end of p-type gate layer 230 on second electrode 235 side and the end of thin film portion 224A in contact with p-type gate layer 230 on second electrode 235 side. Similarly, p-type gate layer 231 extends across thin film portion 224B and thick film portion 224C, and thus when a high voltage is applied to first electrode 234 during OFF, the electric field caused by the voltage is dispersed to the end of p-type gate layer 231 on first electrode 234 side and the end of thin film portion 224B in contact with p-type gate layer 231 on first electrode 234 side. As described above, although a high voltage is applied to either first electrode 234 or second electrode 235 during OFF, the electric field concentration is suppressed, and thus the leakage current is reduced and the withstand voltage can be increased. As described above, according to nitride semiconductor device 201 of the present exemplary embodiment, it is possible to achieve both the reduction of the parasitic capacitance and the improvement of the withstand voltage in the device in which the current can flow bidirectionally.

### Modifications

Then, a plurality of modifications of the third exemplary embodiment will be described. Hereinafter, differences from the third exemplary embodiment will be mainly described, and description of common points will be omitted or simplified.

### Modification 1

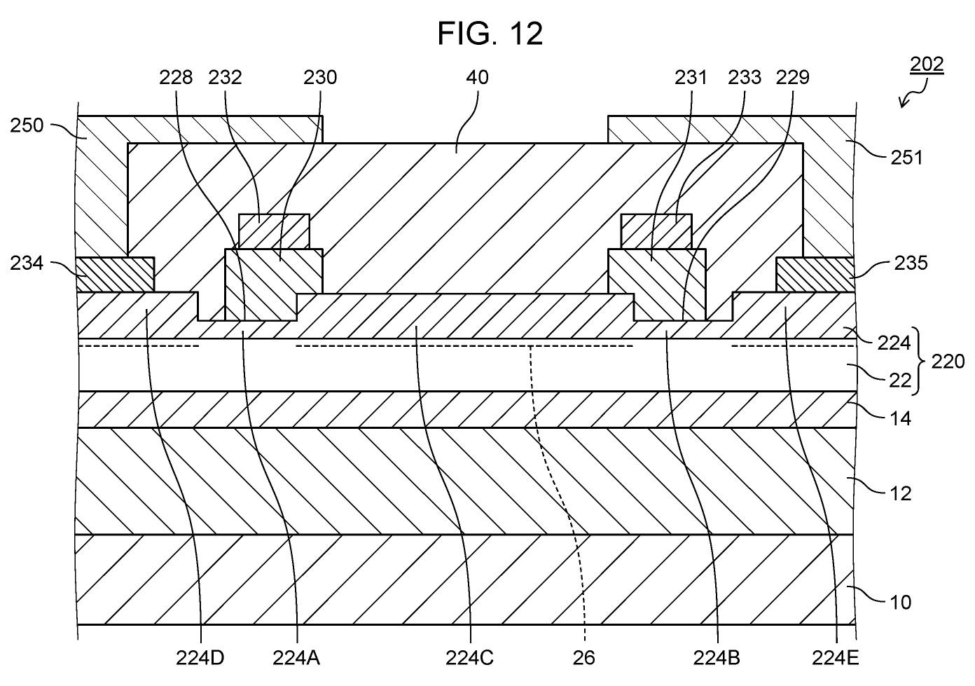

FIG. 12 is a cross-sectional view of nitride semiconductor device 202 according to Modification 1. As illustrated in FIG. 12, in nitride semiconductor device 202, the cross-sectional shape of electron supply layer 224 is different from that of nitride semiconductor device 201 illustrated in FIG. 11.

Specifically, electron supply layer 224 includes thin film portions 224A and 224B and thick film portions 224C, 224D, and 224E. In other words, electron supply layer 224 has gate recesses 228 and 229 which are recesses provided on the upper surface. Thin film portion 224A corresponds to the bottom of gate recess 228, and the side wall of each of thick film portions 224C and 224D on the side of thin film portion 224A corresponds to the side wall of gate recess 228. Thin film portion 224B corresponds to a bottom portion of gate recess 229, and a side wall of each of thick film portions 224C and 224E on the side of thin film portion 224B corresponds to a side wall of gate recess 229.

Thick film portion 224D is an example of the second thick film portion, and is located between thin film portion 224A and first electrode 234 in a plan view of substrate 10. In the present exemplary embodiment, the thick film portion 224D is further provided at a location overlapping first electrode 234 in a plan view. That is, first electrode 234 is provided on thick film portion 224D. Thick film portion 224D does not overlap p-type gate layer 230 in a plan view. Thick film portion 224D is provided with a substantially uniform film thickness continuously from an end of thin film portion 224A to a location overlapping first electrode 234 in a plan view.

A boundary between thin film portion 224A and thick film portion 224D is located between p-type gate layer 230 and first electrode 234 in a plan view of substrate 10. Thin film portion 224A and thick film portion 224D form a step, and the step is not covered with p-type gate layer 230. The side wall of thick film portion 224D located at the boundary is, for example, perpendicular to the main surface of substrate 10.

Thick film portion 224E is an example of the third thick film portion, and is located between thin film portion 224B and second electrode 235 in a plan view of substrate 10. In the present exemplary embodiment, thick film portion 224E is further provided at a location overlapping second electrode 235 in a plan view. That is, second electrode 235 is provided on thick film portion 224E. Thick film portion 224E does not overlap p-type gate layer 231 in a plan view. Thick film portion 224E is provided with a substantially uniform film thickness continuously from an end of thin film portion 224B to a location overlapping second electrode 235 in a plan view.

A boundary between thin film portion 224B and thick film portion 224E is located between p-type gate layer 231 and second electrode 235 in a plan view of substrate 10. Thin film portion 224B and thick film portion 224E form a step, and the step is not covered with p-type gate layer 231. The side wall of thick film portion 224E located at the boundary is, for example, perpendicular to the main surface of substrate 10.

The film thicknesses of thick film portions 224D and 224E may be the same as or different from the film thickness of thick film portion 224C. For example, the film thickness of thick film portion 224D or 224E may be larger than the film thickness of thick film portion 224C.

As described above, in nitride semiconductor device 202 according to the present modification, electron supply layer 224 includes thick film portions 224D and 224E. As a result, in the region between p-type gate layer 230 and first electrode 234 and the region between p-type gate layer 231 and second electrode 235, the concentration of 2DEG 26 generated in the vicinity of the interface between electron supply layer 224 and electron transit layer 22 can be increased. Therefore, the on-resistance of nitride semiconductor device 202 can be reduced. In addition, as with nitride semiconductor device 201 according to the second exemplary embodiment, it is possible to achieve both reduction in parasitic capacitance and improvement in withstand voltage.

Herein, a plan layout of nitride semiconductor device 202 according to the present modification will be described.

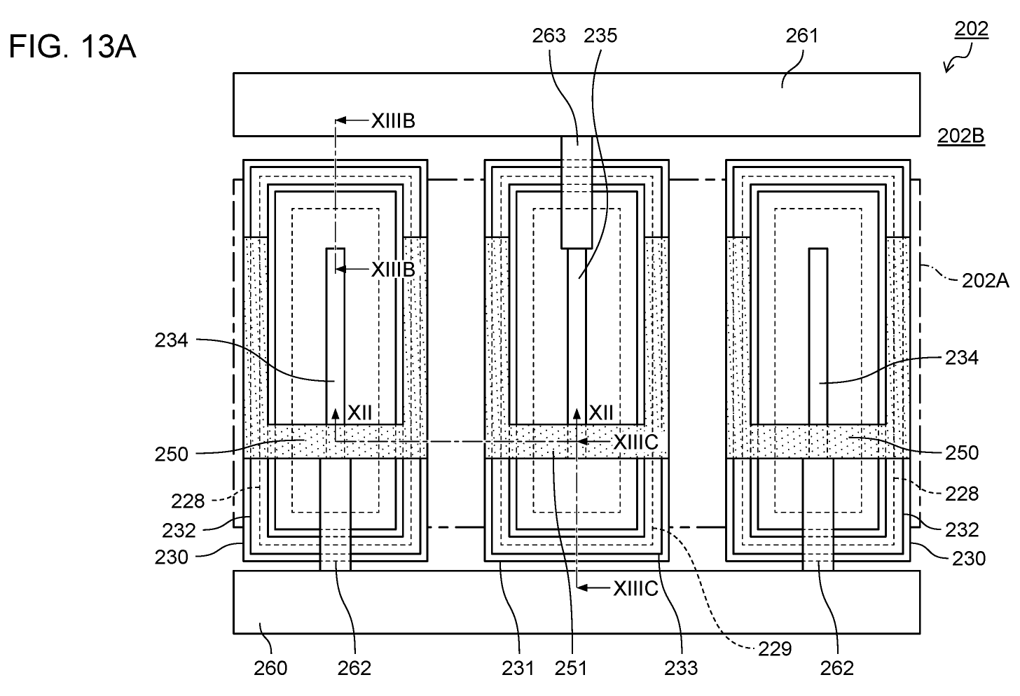

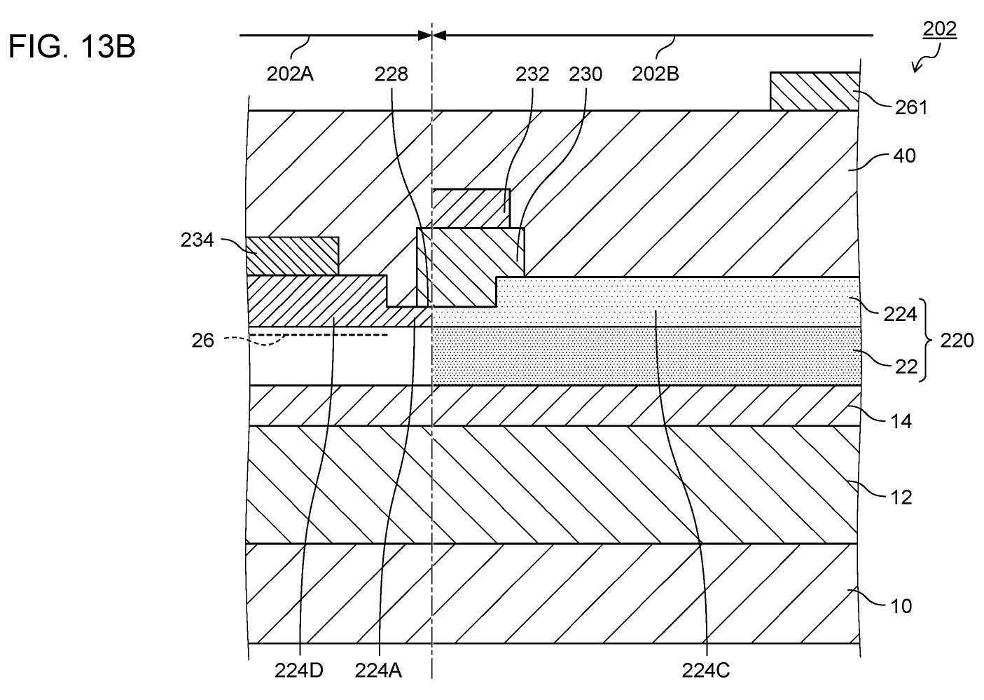

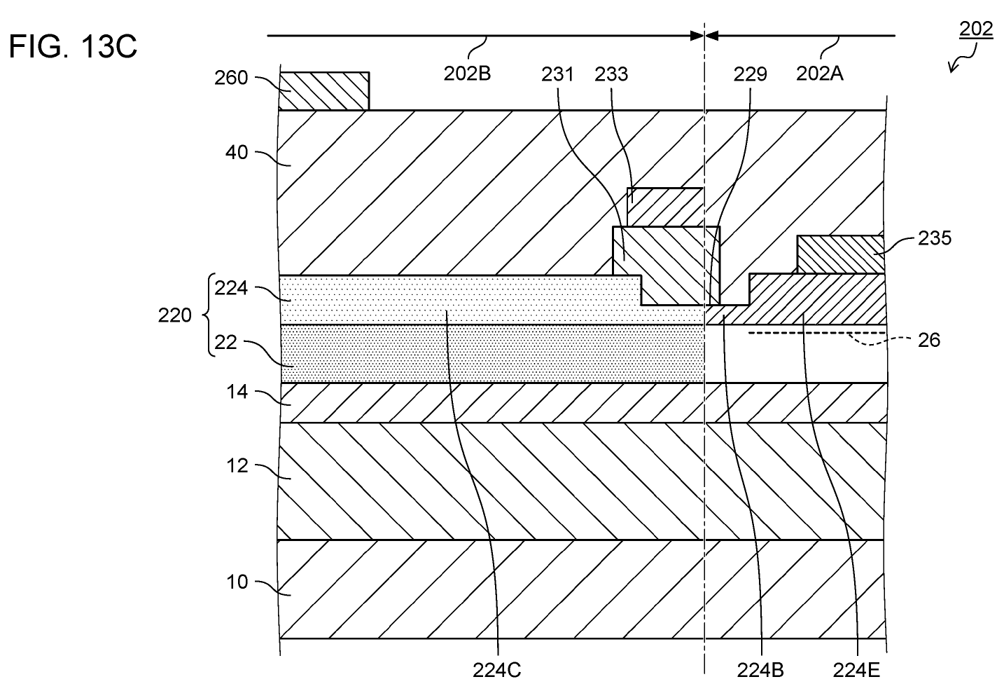

FIG. 13A is a plan view of nitride semiconductor device 202 according to the present modification. FIG. 13B is a cross-sectional view of nitride semiconductor device 202 taken along line XIIIB-XIIIB in FIG. 13A. FIG. 13C is a cross-sectional view of nitride semiconductor device 202 taken along line XIIIC-XIIIC in FIG. 13A. In addition, a cross section of nitride semiconductor device 202 taken along line XII-XII shown in FIG. 13A is as shown in FIG. 12.

As illustrated in FIG. 13A, nitride semiconductor device 202 can be divided into active region 202A and inactive region 202B in a plan view. Active region 202A and inactive region 202B are similar to active region 101A and inactive region 101B according to the second exemplary embodiment, respectively.

Gate electrodes 232 and 233, first electrode 234 and second electrode 235, first field plate 250, second field plate 251, and gate recesses 228 and 229 are provided in active region 202A. In FIG. 13A, first field plate 250 and second field plate 251 are shaded with dots to distinguish them from others.

Each of first electrode 234 and second electrode 235 has, for example, an elongated shape in one direction, and is disposed such that longitudinal directions thereof are parallel to each other. The plurality of first electrodes 234 and the plurality of second electrodes 235 are alternately disposed one by one with gate electrode 232 and p-type gate layer 230, and gate electrode 233 and p-type gate layer 231 interposed therebetween. Gate electrode 232, p-type gate layer 230, and gate recess 228 are annularly provided so as to surround one first electrode 234. Gate electrode 233, p-type gate layer 231, and gate recess 229 are annularly provided so as to surround one second electrode 235. In active region 202A, as illustrated in FIGS. 12, 13B, and 13C, 2DEG 26 is generated in the vicinity of the interface between electron transit layer 22 and electron supply layer 224.

In the present exemplary embodiment, as illustrated in FIG. 13A, first pad 260 and second pad 261 are provided in inactive region 202B. First pad 260 is provided at one end of first electrode 234 in the longitudinal direction. First pad 260 is electrically connected to first electrode 234 via first wiring 262. First wiring 262 is provided across inactive region 202B and active region 202A, and is connected to first electrode 234 provided in active region 202A. As illustrated in FIG. 13C, first pad 260 is provided on the upper surface of interlayer insulating layer 40. First wiring 262 is connected to first electrode 234 via a via hole or the like provided in interlayer insulating layer 40.

Second pad 261 is provided at the other end of first electrode 234 in the longitudinal direction. Second pad 261 is provided so as to sandwich active region 202A with first pad 260. Second pad 261 is electrically connected to second electrode 235 via second wiring 263. Second wiring 263 is provided across inactive region 202B and active region 202A, and is connected to second electrode 235 provided in active region 202A. As illustrated in FIG. 13B, second pad 261 is provided on the upper surface of interlayer insulating layer 40. Second wiring 263 is connected to second electrode 235 via a via hole or the like provided in interlayer insulating layer 40.

First pad 260, second pad 261, first wiring 262, and second wiring 263 are all formed using a metal material. As the metal material that can be used for the pad and the wiring, a metal having a low resistivity and a high thermal conductivity such as Au or Cu can be used. The pad and the wiring are single-layer metal films consisting of a single metal or an alloy of two or more metals, but may be laminated films of a plurality of metal films having different compositions.

Although not illustrated in FIG. 13 A, inactive region 202B may be provided with a first gate pad and a first gate wiring electrically connected to gate electrode 232, a second gate pad and a second gate wiring electrically connected to gate electrode 233, and the like.

In the present exemplary embodiment, as illustrated in FIGS. 13A, 13B, and 13C, gate electrode 232 and p-type gate layer 230, gate electrode 233 and p-type gate layer 231, gate recesses 228 and 229, and thin film portion 224A, thin film portion 224B, and thick film portion 224C of electron supply layer 224 are further located between first electrode 234 and second pad 261 and between second electrode 235 and first pad 260, respectively, in a plan view of substrate 10. As illustrated in FIG. 13B, p-type gate layer 230 extends across thin film portion 224A and thick film portion 224C between first electrode 234 and second pad 261. In addition, as illustrated in FIG. 13C, p-type gate layer 231 extends across thin film portion 224B and thick film portion 224C between second electrode 235 and first pad 260.

A part of the boundary between active region 202A and inactive region 202B coincides with a part of the contour on the inner peripheral side of gate electrode 232 or gate electrode 233. P-type gate layer 230 or 231 is provided across the boundary between active region 202A and inactive region 202B. This makes it possible to suppress an increase in so-called buffer leakage. The location of the boundary between active region 202A and inactive region 202B may be a location overlapping p-type gate layer 230 or 231 in a plan view. For example, the boundary between active region 202A and inactive region 202B may coincide with the boundary between thin film portion 224A or 224B and thick film portion 224C.

As a result, the electric field caused by the high voltage applied to first pad 260 or second pad 261 can be dispersed, and thus the withstand voltage can be further increased. That is, not only the electric field generated in active region 202A but also the electric field generated between active region 202A and inactive region 202B can be dispersed, and the withstand voltage can be further increased.

### Modification 2

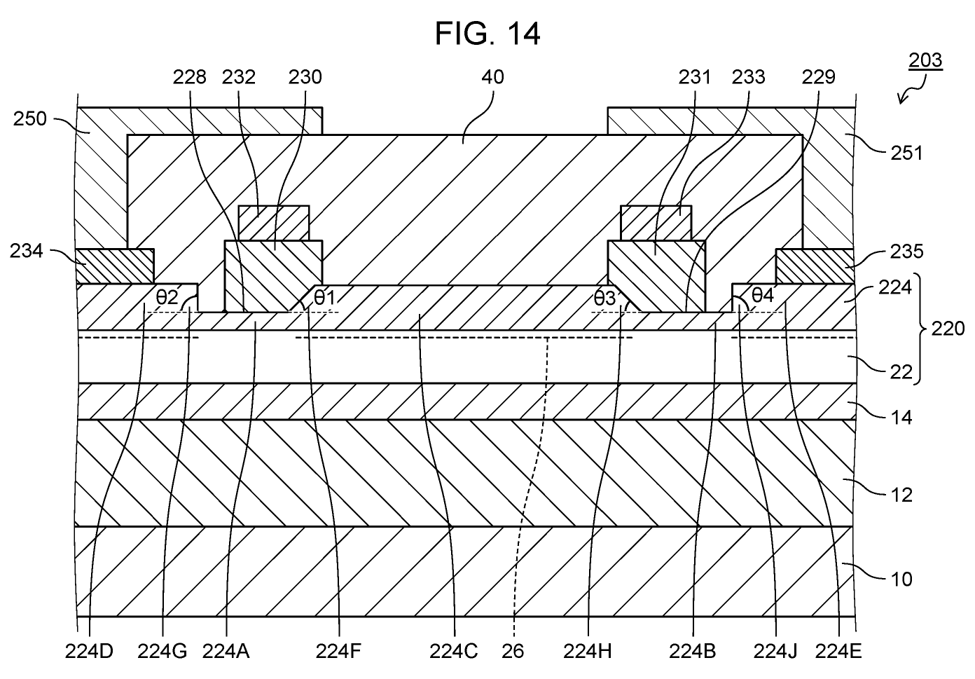

FIG. 14 is a cross-sectional view of nitride semiconductor device 203 according to Modification 2. As illustrated in FIG. 14, nitride semiconductor device 203 is different from nitride semiconductor device 202 illustrated in FIG. 12 in the cross-sectional shape of electron supply layer 224.

In the present modification, as illustrated in FIG. 14, electron supply layer 224 includes thin film portions 224A and 224B, thick film portions 224C, 224D, and 224E, and inclined portions 224F, 224G, 224H, and 224J.

Inclined portion 224F is an example of a first inclined portion with the upper surface inclined, and is located between thin film portion 224A and thick film portion 224C in a plan view of substrate 10. The upper surface of inclined portion 224F is a plane inclined at inclination angle θ1. Inclination angle θ1 is an angle on thick film portion 224C side among angles formed by the upper surface of inclined portion 224F and a surface parallel to the main surface of substrate 10. Inclination angle θ1 is, for example, between 20° and 80°.

Inclined portion 224G is an example of a second inclined portion with the upper surface inclined, and is located between thin film portion 224A and thick film portion 224D in a plan view of substrate 10. The upper surface of inclined portion 224G is a plane inclined at inclination angle θ2. Inclination angle θ2 is an angle on thick film portion 224D side among angles formed by the upper surface of inclined portion 224G and a surface parallel to the main surface of substrate 10. Inclination angle θ2 is larger than inclination angle θ1. Inclination angle θ2 is, for example, between 30° and 90°. The case where inclination angle θ2 is 90° is substantially synonymous with the case where inclined portion 224G is not provided.

Inclined portion 224H is an example of a third inclined portion with the upper surface inclined, and is located between thin film portion 224B and thick film portion 224C in a plan view of substrate 10. The upper surface of inclined portion 224H is a plane inclined at inclination angle θ3. Inclination angle θ3 is an angle on thick film portion 224C side among angles formed by the upper surface of inclined portion 224H and a surface parallel to the main surface of substrate 10. Inclination angle θ3 is, for example, between 20° and 80°. Inclination angle θ3 is equal to inclination angle θ1, but may be different.

Inclined portion 224J is an example of a fourth inclined portion with the upper surface inclined, and is located between thin film portion 224B and thick film portion 224E in a plan view of substrate 10. The upper surface of inclined portion 224J is a plane inclined at inclination angle θ4. Inclination angle θ4 is an angle on thick film portion 224E side among angles formed by the upper surface of inclined portion 224J and a surface parallel to the main surface of substrate 10. Inclination angle θ4 is larger than inclination angle θ3. Inclination angle θ4 is, for example, between 30° and 90°. The case where inclination angle θ4 is 90° is substantially synonymous with the case where inclined portion 224J is not provided. Inclination angle θ4 is equal to inclination angle θ2, but may be different.

In the present modification, p-type gate layer 230 continuously covers the upper surface of inclined portion 224F from thin film portion 224A to thick film portion 224C in contact therewith. As a result, when a high voltage is applied to second electrode 235 in the off state, the electric field is easily dispersed also on the upper surface of inclined portion 224F. In addition, p-type gate layer 231 continuously covers the upper surface of inclined portion 224H from thin film portion 224B to thick film portion 224C in contact therewith. As a result, when a high voltage is applied to first electrode 234 in the off state, the electric field is easily dispersed also on the upper surface of inclined portion 224H. As described above, although a high voltage is applied to either first electrode 234 or second electrode 235 during OFF, the electric field concentration is suppressed, and thus the leakage current is reduced and the withstand voltage can be increased.

### Fourth exemplary embodiment

Then, a fourth exemplary embodiment will be described. In a fourth exemplary embodiment, a nitride semiconductor device including a vertical transistor will be described. Hereinafter, differences from the first to third exemplary embodiments and the respective modifications will be mainly described, and description of common points will be omitted or simplified.

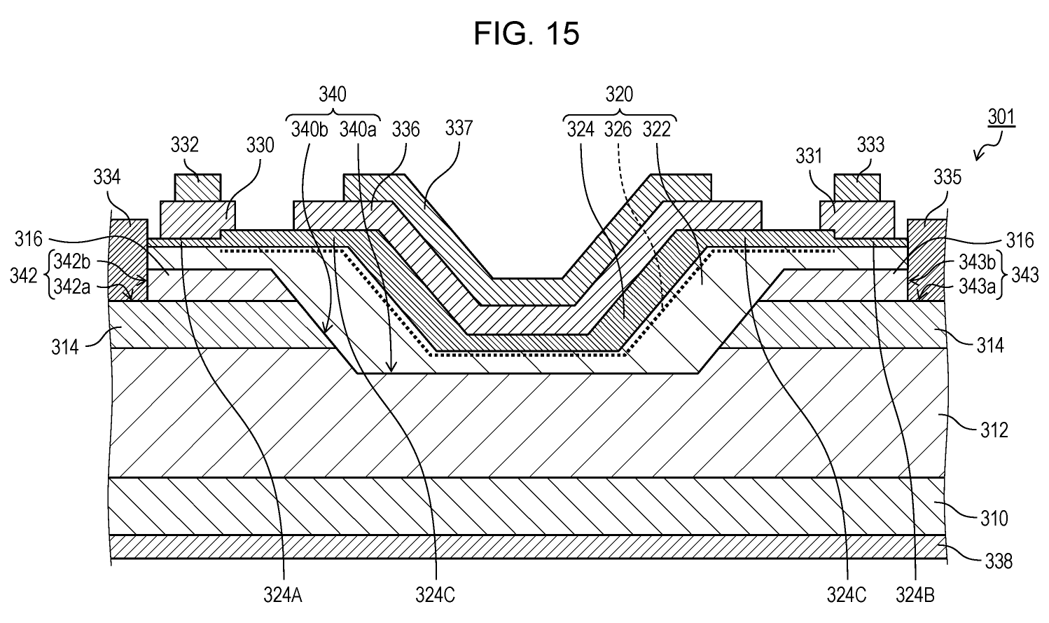

FIG. 15 is a cross-sectional view of nitride semiconductor device 301 according to a fourth exemplary embodiment. Nitride semiconductor device 301 illustrated in FIG. 15 is a normally-off type vertical FET. In nitride semiconductor device 301, source electrodes 334 and 335 are provided above substrate 310, and drain electrode 338 is provided below substrate 310. Therefore, when nitride semiconductor device 301 is on, a drain current flows in the thickness direction of substrate 310, that is, in the vertical direction.

As illustrated in FIG. 15, nitride semiconductor device 301 includes substrate 310, drift layer 312, block layer 314, base layer 316, semiconductor laminate 320, p-type gate layers 330 and 331, gate electrodes 332 and 333, source electrodes 334 and 335, p-type semiconductor layer 336, shielding electrode 337, and drain electrode 338. Semiconductor laminate 320 includes electron transit layer 322 and electron supply layer 324. Substrate 310, electron transit layer 322, electron supply layer 324, p-type gate layers 330 and 331, and gate electrodes 332 and 333 correspond to substrate 10, electron transit layer 22, electron supply layer 224, p-type gate layers 230 and 231, and gate electrodes 232 and 233 of nitride semiconductor device 201 according to the third exemplary embodiment, respectively. The corresponding components will be described focusing on differences.

Substrate 310 is a substrate made of the nitride semiconductor. Substrate 310 is a substrate having conductivity. Substrate 310 is, for example, a substrate made of n⁺-type GaN having a thickness of 300 μm and a carrier concentration of 1 × 10¹⁸ cm⁻³. Substrate 310 may not be a nitride semiconductor substrate. For example, substrate 310 may be a silicon (Si) substrate, a silicon carbide (SiC) substrate, a zinc oxide (ZnO) substrate, or the like.

Drift layer 312 is an example of an n-type third nitride semiconductor layer provided above substrate 310. Drift layer 312 is, for example, a film consisting of n⁻-type GaN having a thickness of 8 μm. A donor concentration of drift layer 312 is, for example, between 1 × 10¹⁵ cm⁻³ and 1 × 10¹⁷ cm⁻³, and is, for example, 1 × 10¹⁶ cm⁻³. The carbon concentration (C concentration) of drift layer 312 is, for example, between 1 × 10¹⁵ cm⁻³ and 2 × 10¹⁷ cm⁻³. Drift layer 312 is provided, for example, in contact with the upper surface (main surface) of substrate 310.

Block layer 314 is an example of a p-type fourth nitride semiconductor layer provided above drift layer 312. Block layer 314 is, for example, a film consisting of p-type GaN having a thickness of 400 nm and a carrier concentration of 1 × 10¹⁷ cm⁻³. Block layer 314 is provided in contact with the upper surface of drift layer 312.

Block layer 314 is formed by crystal growth, but may be formed by, for example, implanting Mg into the formed i-GaN. Further, block layer 314 may not be a p-type nitride semiconductor layer, but may be an insulating layer obtained by, for example, injecting Fe or B.

A high resistance layer having higher resistance than block layer 314 and drift layer 312 may be provided between block layer 314 and drift layer 312. The high resistance layer is, for example, a GaN layer doped with carbon. Providing the high resistance layer allows punch-through to be suppressed, and the withstand voltage of nitride semiconductor device 301 to be increased.

In the present exemplary embodiment, as shown in FIG. 15, block layer 314 is in contact with source electrodes 334 and 335. Therefore, block layer 314 is fixed to the source potential applied to source electrodes 334 and 335. As a result, a high withstand voltage of nitride semiconductor device 301 is achieved. For example, in a case where a reverse voltage is applied to the pn junction formed by block layer 314 and drift layer 312, specifically, in a case where drain electrode 338 has a higher potential than source electrodes 334 and 335, the depletion layer extends to drift layer 312, and thus the withstand voltage of nitride semiconductor device 301 can be increased.

Base layer 316 is an example of a semiconductor layer provided between block layer 314 and electron transit layer 322. Base layer 316 is a high resistance layer having higher resistance than block layer 314. Base layer 316 is, for example, a film consisting of undoped GaN (i-GaN) having a thickness of 200 nm. Base layer 316 is provided in contact with each of block layer 314 and electron transit layer 322.

Base layer 316 may be an insulating layer or a semi-insulating layer. For example, base layer 316 may be a film consisting of carbon-doped GaN (C-GaN). The carbon concentration of base layer 316 is, for example, 3 × 10¹⁷ cm⁻³ or more, but may be 1 × 10¹⁸ cm⁻³or more. Base layer 316 may include n-type impurities such as Si. The concentration of the n-type impurity included in base layer 316 is lower than the carbon concentration and the oxygen concentration of base layer 316, and may be, for example, less than or equal to 5 × 10¹⁶ cm⁻³, or less than or equal to 2 × 10¹⁶ cm⁻³. Base layer 316 may not be provided.

Nitride semiconductor device 301 is provided with opening 340 that penetrates block layer 314 and reaches drift layer 312. Opening 340 is formed such that the opening area increases as the distance from substrate 310 increases. Specifically, bottom surface 340a of opening 340 is parallel to the main surface of substrate 310, and side wall 340b of opening 340 is inclined obliquely. Side wall 340b may be perpendicular to bottom surface 340a.

Semiconductor laminate 320 is provided so as to cover the inner surface of opening 340 and the upper side of block layer 314. Specifically, electron transit layer 322 covers bottom surface 340a and side wall 340b of opening 340 and the upper surface of base layer 316 in contact with each other. Each of electron transit layer 322 and electron supply layer 324 has a curved shape along the inner surface of opening 340. 2DEG 326 generated in the vicinity of the interface between electron transit layer 322 and electron supply layer 324 also has a curved shape along the inner surface of opening 340.

Electron supply layer 324 includes thin film portions 324A and 324B and thick film portion 324C.

Thin film portion 324A is an example of a first thin film portion, and is located between gate electrode 332 and source electrode 334 in a plan view of substrate 310. In the present exemplary embodiment, thin film portion 324A is further provided at a location overlapping p-type gate layer 330 in a plan view. Thin film portion 324A is provided with a substantially uniform film thickness continuously from a location overlapping p-type gate layer 330 to a location in contact with source electrode 334.

Thin film portion 324B is an example of a second thin film portion, and is located between gate electrode 333 and source electrode 335 in a plan view of substrate 310. In the present exemplary embodiment, thin film portion 324B is further provided at a location overlapping p-type gate layer 331 in a plan view. Thin film portion 324B is provided with a substantially uniform film thickness continuously from a location overlapping p-type gate layer 331 to a location in contact with source electrode 335.

Thick film portion 324C is an example of the first thick film portion, and is located between thin film portion 324A and thin film portion 324B in a plan view of substrate 310. In the present exemplary embodiment, thick film portion 324C is further provided at a location overlapping p-type gate layer 330 and a location overlapping p-type gate layer 331 in a plan view. Thick film portion 324C has a shape along the inner surface of opening 340. Film thickness of thick film portion 324C is different among an inclined portion which is a portion parallel to side wall 340b of opening 340, a bottom surface portion which is a portion parallel to bottom surface 340a of opening 340, and an upper surface portion that is a portion outside opening 340, but may be the same. Film thickness of thick film portion 324C at least on the upper surface portion is larger than the film thickness of each of thin film portions 324A and 324B.

P-type gate layer 330 is an example of a first threshold adjustment layer, and is a p-type nitride semiconductor layer provided between source electrode 334 and source electrode 335. Specifically, p-type gate layer 330 is provided between bottom surface 340a of opening 340 and source electrode 334 in a plan view of substrate 310.

P-type gate layer 331 is an example of a second threshold adjustment layer, and is a p-type nitride semiconductor layer provided between p-type gate layer 330 and source electrode 335. Specifically, p-type gate layer 331 is provided between bottom surface 340a of opening 340 and source electrode 335 in a plan view of substrate 310. P-type gate layer 331 is provided so as to sandwich opening 340 with p-type gate layer 330. For example, none of p-type gate layers 330 and 331 overlaps both bottom surface 340a and side wall 340b of opening 340 in a plan view, and overlaps the upper surface of base layer 316.

Gate electrode 332 is an example of a first gate electrode, and is provided above p-type gate layer 330. Gate electrode 332 is electrically connected to p-type gate layer 330. Specifically, gate electrode 332 is provided in contact with the upper surface of p-type gate layer 330.

Gate electrode 333 is an example of a second gate electrode, and is provided above p-type gate layer 331. Gate electrode 333 is electrically connected to p-type gate layer 331. Specifically, gate electrode 333 is provided in contact with the upper surface of p-type gate layer 331.

In the present exemplary embodiment, gate electrodes 332 and 333 are electrically connected to each other. Specifically, a gate pad (not illustrated) and the like are electrically connected to gate electrodes 332 and 333, and gate potentials of the same magnitude are supplied.

In the present exemplary embodiment, as in the other exemplary embodiments, p-type gate layer 330 and gate electrode 332 extend across thin film portion 324A and thick film portion 324C in a plan view of substrate 310. An end of p-type gate layer 330 on source electrode 334 side is located on thin film portion 324A. In addition, p-type gate layer 331 and gate electrode 333 extend across thin film portion 324B and thick film portion 324C in a plan view of substrate 310. An end of p-type gate layer 331 on source electrode 335 side is located on thin film portion 324B. Thus, as in the other exemplary embodiments, in nitride semiconductor device 301, both the reduction of the parasitic capacitance and the improvement of the withstand voltage can be achieved.

Source electrode 334 is an example of a first electrode, and is in contact with semiconductor laminate 320. In the present exemplary embodiment, source electrode 334 is provided at a location away from opening 340 in a plan view of substrate 310.

Source electrode 335 is an example of a second electrode, and is in contact with semiconductor laminate 320. In the present exemplary embodiment, source electrode 335 is provided at a location away from opening 340 in a plan view of substrate 310. Specifically, source electrode 335 is provided so as to sandwich opening 340 with source electrode 334. Opening 340, p-type gate layers 330 and 331, gate electrodes 332 and 333, p-type semiconductor layer 336, and shielding electrode 337 are provided between source electrode 335 and source electrode 334. Source electrodes 334 and 335 are electrically connected to each other. Specifically, a source pad (not illustrated) and the like are electrically connected to source electrodes 334 and 335, and source potentials of the same magnitude are supplied thereto.

In the present exemplary embodiment, source electrode 334 is provided so as to cover source opening 342. Source electrode 335 is provided so as to cover source opening 343. When on, source electrode 334 can be in direct contact with 2DEG 326 exposed on side wall 342b of source opening 342. In addition, source electrode 335 is provided so as to cover source opening 343. When on, source electrode 335 can be in direct contact with 2DEG 326 exposed on side wall 343b of source opening 343. Thus, the contact resistance to the channel of each of source electrodes 334 and 335 can be reduced.

Source openings 342 and 343 penetrate semiconductor laminate 320 and base layer 316 and reach block layer 314. Bottom surfaces 342a and 343a of source openings 342 and 343 are the upper surface of block layer 314, but the present disclosure is not limited thereto. Bottom surfaces 342a and 343a may be located below the interface between block layer 314 and base layer 316, that is, at a location close to substrate 310.

P-type semiconductor layer 336 is an example of a p-type fifth nitride semiconductor layer, and is provided above semiconductor laminate 320 at a location overlapping bottom surface 340a of opening 340 in a plan view of substrate 310. Specifically, p-type semiconductor layer 336 is provided in contact with each of the upper surface of thick film portion 324C of electron supply layer 324 and the lower surface of shielding electrode 337. P-type semiconductor layer 336 overlaps each of bottom surface 340a and side wall 340b of opening 340 in a plan view of substrate 310. P-type semiconductor layer 336 may overlap only bottom surface 340a of opening 340 and may not overlap side wall 340b in a plan view of substrate 310. Alternatively, p-type semiconductor layer 336 may overlap not only opening 340 but also the upper surface of block layer 314 in a plan view of substrate 310.

P-type semiconductor layer 336 is electrically separated from both p-type gate layers 330 and 331. A source potential is supplied to p-type semiconductor layer 336 via shielding electrode 337. P-type semiconductor layer 336 is, for example, a film consisting of p-type GaN or AlGaN having a thickness of 200 nm and a carrier concentration of 1 × 10¹⁹ cm⁻³. The thickness and the carrier concentration of p-type semiconductor layer 336 are merely examples, and can be appropriately changed.

Shielding electrode 337 is an example of a third electrode, and is provided above p-type semiconductor layer 336. Specifically, shielding electrode 337 is provided in contact with the upper surface of p-type semiconductor layer 336. Shielding electrode 337 is set to the same potential as source electrodes 334 and 335.

Shielding electrode 337 is formed using, for example, a conductive material such as metal. For example, shielding electrode 337 may be made of a material that is ohmic-connected to a p-type nitride semiconductor such as p-type GaN. For example, Pd, a Ni-based material, WSi, Au, or the like can be used as a material for forming shielding electrode 337.

Providing p-type semiconductor layer 336 in this manner allows lines of electric force extending from drain electrode 338 to be terminated in p-type semiconductor layer 336 and block layer 314, and thus the parasitic capacitance Cgd between the gate and the drain can be reduced. Therefore, it is possible to speed up the switching of the FET with low loss.

Drain electrode 338 is provided below substrate 310. Specifically, drain electrode 338 is provided in contact with the lower surface of substrate 310.

As described above, also in nitride semiconductor device 301 including the vertical transistor, p-type gate layers 330 and 331 are provided so as to extend across each of thin film portions 324A and 324B, and thick film portion 324C of electron supply layer 324. As a result, similarly to nitride semiconductor device 201 according to the third exemplary embodiment, it is possible to achieve both the reduction of the parasitic capacitance and the improvement of the withstand voltage.

An example of a method for producing nitride semiconductor device 301 is as follows. First, a semiconductor film to be a base of drift layer 312, block layer 314, and base layer 316 is formed above substrate 310 by crystal growth such as an epitaxial growth method such as an MOCVD method or an HVPE method. Adjusting the growth conditions such as the raw material, the growth temperature, and the growth time allows the composition, the film thickness, the impurity concentration, and the like to be set to values suitable for each layer. The formation of base layer 316 may be omitted. Then, opening 340 that penetrates base layer 316 and block layer 314 and reaches drift layer 312 is formed. Opening 340 is formed by, for example, dry etching or the like.

Then, a semiconductor film on which electron transit layer 322 and electron supply layer 324 are based is sequentially formed by crystal growth such as an epitaxial growth method such as a MOCVD method or an HVPE method so as to cover the inner surface of opening 340 and the upper surface of base layer 316. Adjusting the growth conditions such as the raw material, the growth temperature, and the growth time allows the composition, the film thickness, the impurity concentration, and the like to be set to values suitable for each layer. Electron transit layer 322 and electron supply layer 324 are continuously formed in the same growth furnace without being exposed to the atmosphere in the middle. A part of the semiconductor film on which electron supply layer 324 is based is removed by dry etching or the like to form thin film portions 324A and 324B.

Then, a p-type semiconductor film as a base of p-type gate layers 330 and 331 and p-type semiconductor layer 336 is formed by crystal growth such as an epitaxial growth method such as an MOCVD method or an HVPE method so as to extend across each of thin film portions 324A and 324B, and thick film portion 324C. Then, p-type gate layers 330 and 331 and p-type semiconductor layer 336 are formed by patterning the formed p-type semiconductor film into a predetermined shape. The patterning is performed by dry etching or the like.

Then, after source openings 342 and 343 are formed by dry etching or the like, source electrodes 334 and 335, gate electrodes 332 and 333, shielding electrode 337, and drain electrode 338 are formed. The order of forming source electrodes 334 and 335, gate electrodes 332 and 333, shielding electrode 337, and drain electrode 338 is not particularly limited.

As described above, nitride semiconductor device 301 shown in FIG. 15 can be produced. The above-described method for producing nitride semiconductor device 301 is merely an example, and can be appropriately changed.

### Modifications

Then, a plurality of modifications of the fourth exemplary embodiment will be described. Hereinafter, differences from the fourth exemplary embodiment will be mainly described, and description of common points will be omitted or simplified.

### Modification 1

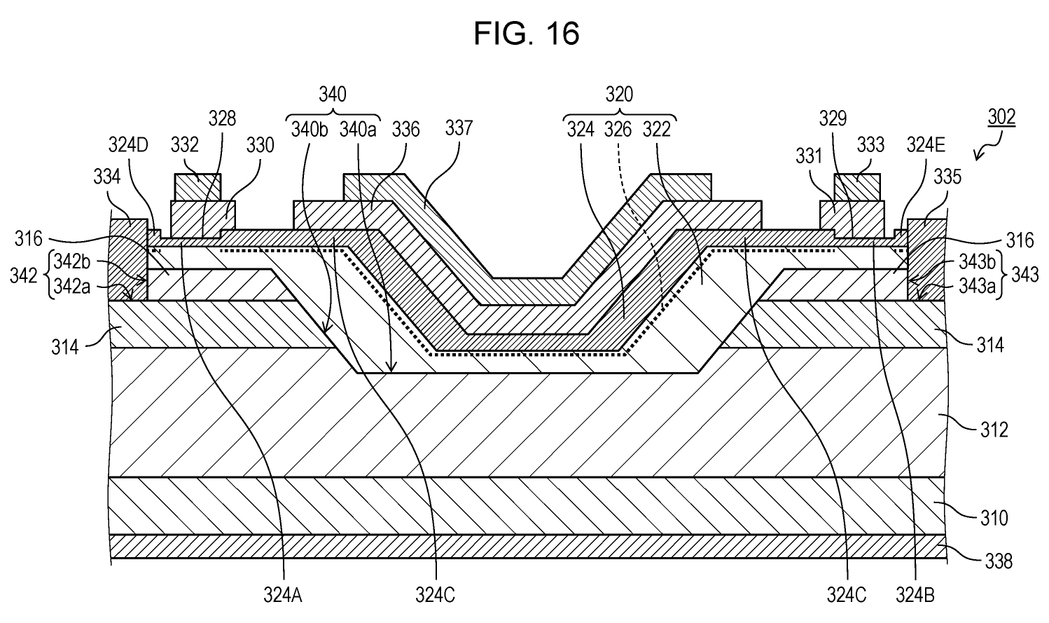

FIG. 16 is a cross-sectional view of nitride semiconductor device 302 according to Modification 1. As illustrated in FIG. 16, in nitride semiconductor device 302, the cross-sectional shape of electron supply layer 324 is different from that of nitride semiconductor device 301 illustrated in FIG. 15.

Specifically, electron supply layer 324 includes thin film portions 324A and 324B and thick film portions 324C, 324D, and 324E. In other words, electron supply layer 324 has gate recesses 328 and 329 which are recesses provided on the upper surface. Thin film portion 324A corresponds to the bottom of gate recess 328, and the side wall of each of thick film portions 324C and 324D on the side of thin film portion 324A corresponds to the side wall of gate recess 328. Thin film portion 324B corresponds to a bottom portion of gate recess 329, and a side wall of each of thick film portions 324C and 324E on the side of thin film portion 324B corresponds to a side wall of gate recess 329.

Thick film portions 324D and 324E are the same as thick film portions 224D and 224E according to Modification 1 of the second exemplary embodiment, respectively. In addition, gate recesses 328 and 329 are similar to gate recesses 228 and 229 according to Modification 1 of the second exemplary embodiment, respectively.

As described above, in nitride semiconductor device 302 according to the present modification, electron supply layer 324 includes thick film portions 324D and 324E. As a result, in the region between p-type gate layer 330 and source electrode 334 and the region between p-type gate layer 331 and source electrode 335, the concentration of 2DEG 326 generated in the vicinity of the interface between each of thick film portions 324D and 324E and electron transit layer 322 can be increased. Therefore, the on-resistance of nitride semiconductor device 302 can be reduced. In addition, as with nitride semiconductor device 301 according to the fourth exemplary embodiment, it is possible to achieve both reduction in parasitic capacitance and improvement in withstand voltage.

### Modification 2

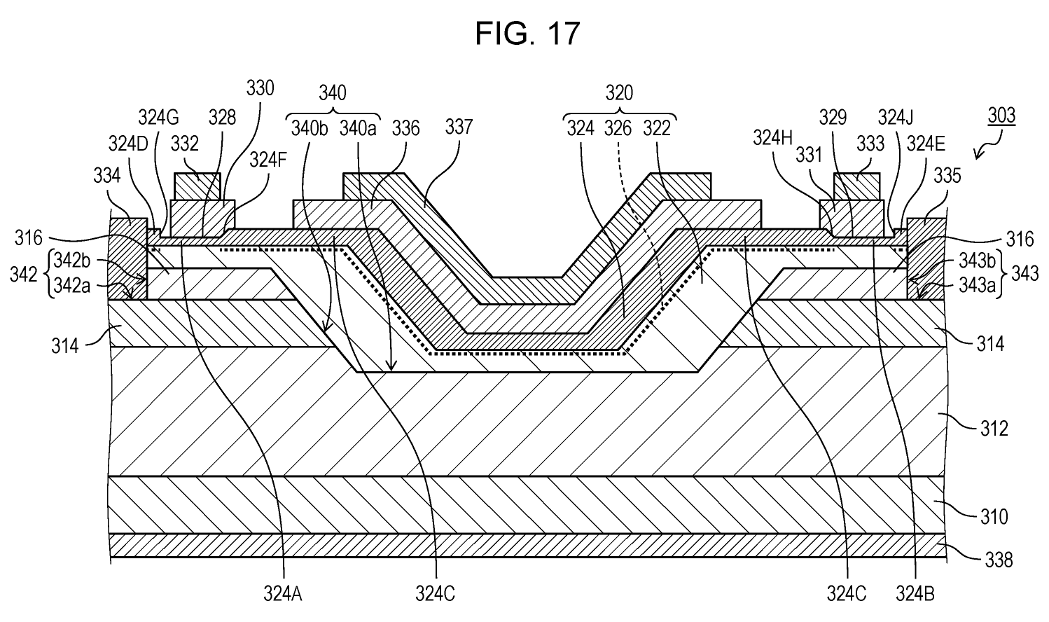

FIG. 17 is a cross-sectional view of nitride semiconductor device 303 according to Modification 2. As illustrated in FIG. 17, nitride semiconductor device 303 is different from nitride semiconductor device 302 illustrated in FIG. 16 in the cross-sectional shape of electron supply layer 324.

In the present modification, as illustrated in FIG. 17, electron supply layer 324 includes thin film portions 324A and 324B, thick film portions 324C, 324D, and 324E, and inclined portions 324F, 324G, 324H, and 324J. Inclined portions 324F, 324G, 324H, and 324J are similar to inclined portions 224F, 224G, 224H, and 224J according to Modification 2 of the second exemplary embodiment, respectively.

In the present modification, p-type gate layer 330 continuously covers the upper surface of inclined portion 324F from thin film portion 324A to thick film portion 324C in contact therewith. In addition, p-type gate layer 331 continuously covers the upper surface of inclined portion 324H from thin film portion 324B to thick film portion 324C in contact therewith. As a result, as with nitride semiconductor device 301 according to the fourth exemplary embodiment, it is possible to achieve both reduction in parasitic capacitance and improvement in withstand voltage.

### Fifth exemplary embodiment

Then, a fifth exemplary embodiment will be described. The fifth exemplary embodiment is different from the fourth exemplary embodiment in the location where the gate electrode of the vertical transistor is provided. Hereinafter, differences from the fourth exemplary embodiment will be mainly described, and description of common points will be omitted or simplified.

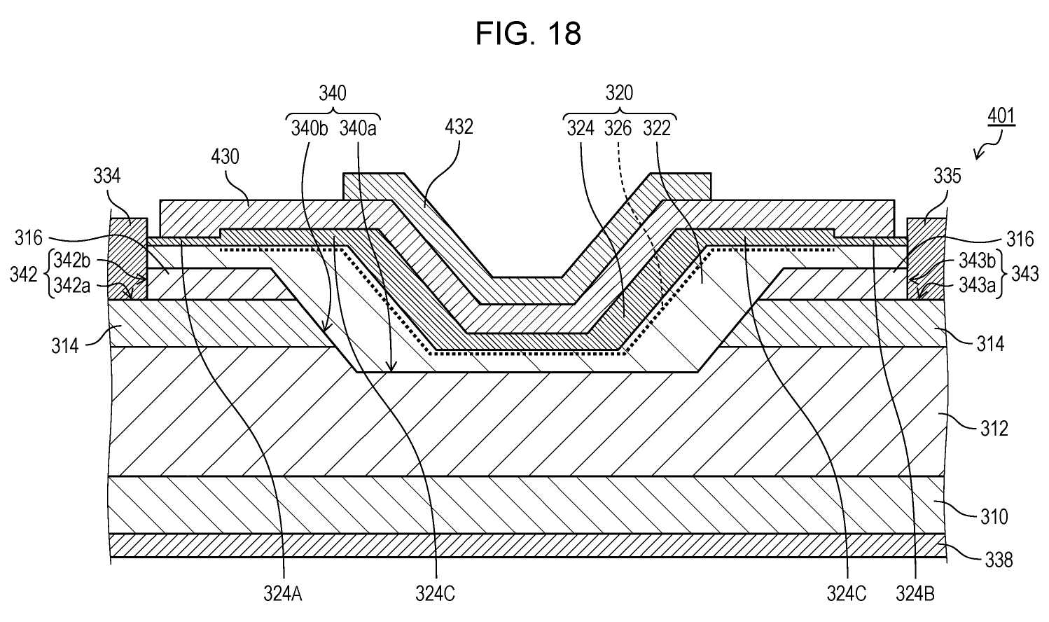

FIG. 18 is a cross-sectional view of nitride semiconductor device 401 according to a fifth exemplary embodiment. Nitride semiconductor device 401 illustrated in FIG. 18 is different from nitride semiconductor device 301 illustrated in FIG. 15 in that p-type gate layer 430 and gate electrode 432 are provided instead of p-type gate layers 330 and 331, gate electrodes 332 and 333, p-type semiconductor layer 336, and shielding electrode 337.

P-type gate layer 430 is an example of a threshold adjustment layer, and is provided above semiconductor laminate 320 at a location overlapping bottom surface 340a of opening 340 in a plan view of substrate 310. Specifically, p-type gate layer 430 is provided in contact with each of the upper surface of thick film portion 324C of electron supply layer 324 and the lower surface of gate electrode 432. P-type gate layer 430 overlaps each of bottom surface 340a and side wall 340b of opening 340 and the upper surface of block layer 314 in a plan view of substrate 310.

P-type gate layer 430 extends across thin film portion 324A and thick film portion 324C and extends across thin film portion 324B and thick film portion 324C in a plan view of substrate 310. Specifically, p-type gate layer 430 is provided with a substantially uniform film thickness continuously covering thick film portion 324C from thin film portion 324A to thin film portion 324B. An end of p-type gate layer 430 on source electrode 334 side is located on thin film portion 324A. An end of p-type gate layer 430 on source electrode 335 side is located on thin film portion 324B.

P-type gate layer 430 is provided between source electrode 334 and source electrode 335, and is electrically separated from both of source electrodes 334 and 335. A gate potential is supplied to p-type gate layer 430 via gate electrode 432. P-type gate layer 430 is, for example, a film consisting of p-type GaN or AlGaN having a thickness of 200 nm and a carrier concentration of 1 × 10¹⁹ cm⁻³. The thickness and the carrier concentration of p-type gate layer 430 are merely examples, and can be appropriately changed.

Gate electrode 432 is provided above p-type gate layer 430. Specifically, gate electrode 432 is electrically connected to p-type gate layer 430. Gate electrode 432 is provided in contact with the upper surface of p-type gate layer 430. In the present exemplary embodiment, gate electrode 432 is provided at a location overlapping bottom surface 340a of opening 340 in a plan view of substrate 310.

Gate electrode 432 is formed using, for example, a conductive material such as metal. For example, gate electrode 432 may be made of a material that is ohmic-connected to a p-type nitride semiconductor such as p-type GaN. For example, Pd, a Ni-based material, WSi, Au, or the like can be used as a material for forming gate electrode 432.

Also in the present exemplary embodiment, as in the other exemplary embodiments, when nitride semiconductor device 401 is off, the generation of 2DEG 326 in the vicinity of the interface between each of thin film portions 324A and 324B and electron transit layer 322 is suppressed. The end of p-type gate layer 430 on source electrode 334 side is located on thin film portion 324A and the end of p-type gate layer 430 on source electrode 335 side is located on thin film portion 324B, and thus the area where p-type gate layer 430 and 2DEG 326 face each other is reduced. Therefore, the parasitic capacitance between gate electrode 432 and each of source electrodes 334 and 335 can be reduced. In addition, nitride semiconductor device 401 according to the present exemplary embodiment is a so-called vertical device and is excellent in withstand voltage. As described above, according to nitride semiconductor device 401 of the present exemplary embodiment, it is possible to achieve both the reduction of the parasitic capacitance and the improvement of the withstand voltage.

### Modifications

Then, a plurality of modifications of the fifth exemplary embodiment will be described. Hereinafter, differences from the fifth exemplary embodiment will be mainly described, and description of common points will be omitted or simplified.

### Modification 1

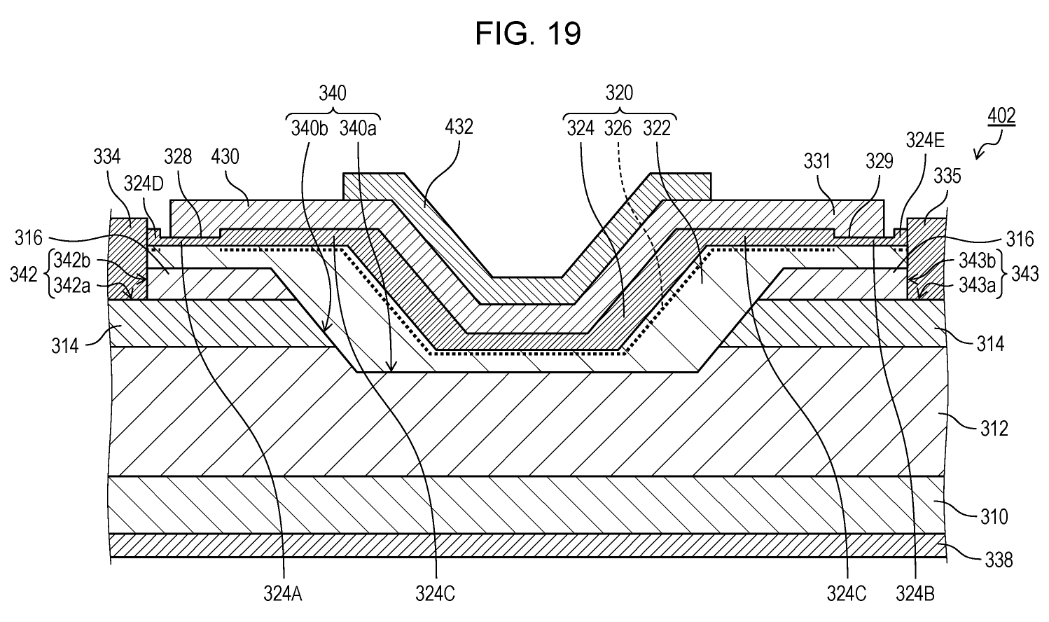

FIG. 19 is a cross-sectional view of nitride semiconductor device 402 according to Modification 1. As illustrated in FIG. 19, in nitride semiconductor device 402, the cross-sectional shape of electron supply layer 324 is different from that of nitride semiconductor device 401 illustrated in FIG. 18. The cross-sectional shape of electron supply layer 324 in nitride semiconductor device 402 is the same as the cross-sectional shape of electron supply layer 324 in nitride semiconductor device 302 illustrated in FIG. 16.

In nitride semiconductor device 402 according to the present modification, electron supply layer 324 includes thick film portions 324D and 324E. As a result, in the region between p-type gate layer 430 and each of source electrodes 334 and 335, the concentration of 2DEG 326 generated in the vicinity of the interface between each of thick film portions 324D and 324E and electron transit layer 322 can be increased. Therefore, the on-resistance of nitride semiconductor device 402 can be reduced. In addition, as with nitride semiconductor device 401 according to the fifth exemplary embodiment, it is possible to achieve both reduction in parasitic capacitance and improvement in withstand voltage.

### Modification 2

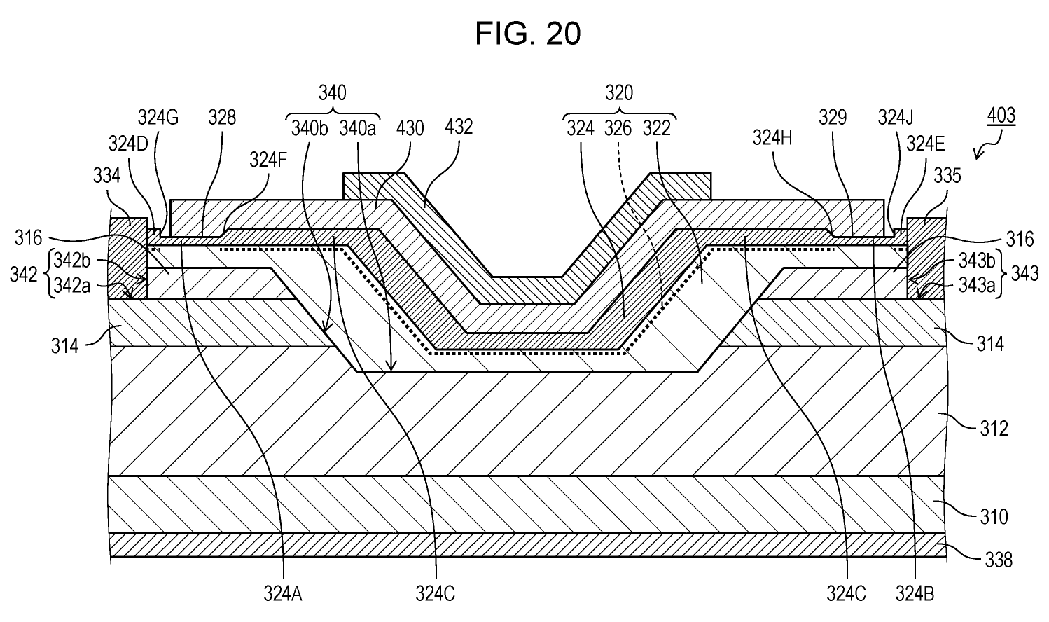

FIG. 20 is a cross-sectional view of nitride semiconductor device 403 according to Modification 2. As illustrated in FIG. 20, nitride semiconductor device 403 is different from nitride semiconductor device 402 illustrated in FIG. 19 in the cross-sectional shape of electron supply layer 324. The cross-sectional shape of electron supply layer 324 in nitride semiconductor device 403 is the same as the cross-sectional shape of electron supply layer 324 in nitride semiconductor device 303 illustrated in FIG. 17.

In the present modification, p-type gate layer 430 continuously covers the upper surface of inclined portion 324F, the upper surface of thick film portion 324C, and the upper surface of inclined portion 324H in contact with each other from thin film portion 324A to thin film portion 324B. As a result, as with nitride semiconductor device 401 according to the fifth exemplary embodiment, it is possible to achieve both reduction in parasitic capacitance and improvement in withstand voltage.

### Other exemplary embodiments

The nitride semiconductor device according to one or more aspects has been described above based on the exemplary embodiments, but the present disclosure is not limited to these exemplary embodiments. Configurations in which various modifications conceivable by those skilled in the art are applied to the present exemplary embodiment and configurations constructed by combining components in different exemplary embodiments are also included in the scope of the present disclosure without departing from the gist of the present disclosure.

In addition, various changes, replacements, additions, omissions, and the like can be made in each of the above exemplary embodiments within the scope of claims or equivalents thereof.

According to the present disclosure, it is possible to achieve both the reduction of the parasitic capacitance and the improvement of the withstand voltage.

The nitride semiconductor device according to the present disclosure is useful as, for example, a power device used in a power supply circuit, an inverter circuit, or the like of an electric device.

What is claimed is:

1. A nitride semiconductor device comprising:
a substrate;
a semiconductor laminate disposed above the substrate and including a channel;
a source electrode and a drain electrode each being in contact with the semiconductor laminate;
a threshold adjustment layer located between the source electrode and the drain electrode; and
a gate electrode disposed above the threshold adjustment layer, wherein
the semiconductor laminate includes:
a first nitride semiconductor layer; and
a second nitride semiconductor layer disposed above the first nitride semiconductor layer,
the second nitride semiconductor layer includes:
a first thin film portion located between the gate electrode and the source electrode in a plan view of the substrate; and
a first thick film portion that is located between the gate electrode and the drain electrode in a plan view of the substrate and is thicker than the first thin film portion,
the threshold adjustment layer extends across the first thin film portion and the first thick film portion in a plan view of the substrate, and
an end of the threshold adjustment layer on the source electrode side is located on the first thin film portion.

2. The nitride semiconductor device according to claim 1, wherein
the source electrode is disposed on the first thin film portion, and
the drain electrode is disposed on the first thick film portion.

3. The nitride semiconductor device according to claim 1, wherein
the second nitride semiconductor layer further includes a second thick film portion located between the first thin film portion and the source electrode in a plan view of the substrate,
the source electrode is disposed on the second thick film portion, and
the drain electrode is disposed on the first thick film portion.

4. The nitride semiconductor device according to claim 1, wherein
the second nitride semiconductor layer further includes a second thin film portion that is located between the first thick film portion and the drain electrode in a plan view of the substrate and is thinner than the first thick film portion,
the source electrode is disposed on the first thin film portion, and
the drain electrode is disposed on the second thin film portion.

5. The nitride semiconductor device according to claim 1, wherein
the second nitride semiconductor layer further includes a first inclined portion located between the first thin film portion and the first thick film portion in a plan view of the substrate and having an inclined upper surface.

6. The nitride semiconductor device according to claim 3, wherein
the second nitride semiconductor layer further includes:
a first inclined portion located between the first thin film portion and the first thick film portion in a plan view of the substrate and having an inclined upper surface; and
a second inclined portion located between the first thin film portion and the second thick film portion in a plan view of the substrate and having an inclined upper surface, and
an inclination of the inclined upper surface of the first inclined portion is gentler than an inclination of the inclined upper surface of the second inclined portion.

7. The nitride semiconductor device according to claim 1, wherein the threshold adjustment layer is a p-type nitride semiconductor layer.

8. The nitride semiconductor device according to claim 1, wherein
the nitride semiconductor device is divided into an active region and an inactive region in a plan view of the substrate,
the source electrode and the drain electrode are disposed in the active region,
the nitride semiconductor device further includes a drain pad disposed in the inactive region and electrically connected to the drain electrode,
the first thick film portion, the first thin film portion, and the threshold adjustment layer are all further located between the source electrode and the drain pad in a plan view of the substrate, and
the threshold adjustment layer extends across the first thin film portion and the first thick film portion between the source electrode and the drain pad in a plan view of the substrate.

9. A nitride semiconductor device comprising:
a substrate;
a semiconductor laminate disposed above the substrate and including a channel;
a first electrode and a second electrode each being in contact with the semiconductor laminate;
a first threshold adjustment layer located between the first electrode and the second electrode;
a second threshold adjustment layer located between the first threshold adjustment layer and the second electrode;
a first gate electrode disposed above the first threshold adjustment layer; and
a second gate electrode disposed above the second threshold adjustment layer, wherein
the semiconductor laminate includes:
a first nitride semiconductor layer; and
a second nitride semiconductor layer disposed above the first nitride semiconductor layer,
the second nitride semiconductor layer includes:
a first thin film portion located between the first gate electrode and the first electrode in a plan view of the substrate;
a second thin film portion located between the second gate electrode and the second electrode in a plan view of the substrate; and
a first thick film portion that is located between the first thin film portion and the second thin film portion in a plan view of the substrate and is thicker than both of the first thin film portion and the second thin film portion,
the first threshold adjustment layer extends across the first thin film portion and the first thick film portion in a plan view of the substrate,
the second threshold adjustment layer extends across the second thin film portion and the first thick film portion in a plan view of the substrate,
an end of the first threshold adjustment layer on the first electrode side is located on the first thin film portion, and
an end of the second threshold adjustment layer on the second electrode side is located on the second thin film portion.

10. The nitride semiconductor device according to claim 9, wherein
the first electrode is disposed on the first thin film portion, and
the second electrode is disposed on the second thin film portion.

11. The nitride semiconductor device according to claim 9, wherein
the second nitride semiconductor layer further includes:
a second thick film portion located between the first thin film portion and the first electrode in a plan view of the substrate; and
a third thick film portion located between the second thin film portion and the second electrode in a plan view of the substrate,
the first electrode is disposed on the second thick film portion, and
the second electrode is disposed on the third thick film portion.

12. The nitride semiconductor device according to claim 9, wherein
the second nitride semiconductor layer further includes:
a first inclined portion located between the first thin film portion and the first thick film portion in a plan view of the substrate and having an inclined upper surface; and
a third inclined portion located between the second thin film portion and the first thick film portion in a plan view of the substrate and having an inclined upper surface.

13. The nitride semiconductor device according to claim 9, further comprising:
an n-type third nitride semiconductor layer disposed above the substrate;
a p-type fourth nitride semiconductor layer disposed above the third nitride semiconductor layer; and
a drain electrode disposed below the substrate,
wherein the semiconductor laminate is disposed to cover an inner surface of an opening penetrating the fourth nitride semiconductor layer and reaching the third nitride semiconductor layer and an upper side of the fourth nitride semiconductor layer,
the opening is located between the first electrode and the second electrode in a plan view of the substrate,
the first electrode and the second electrode are each a source electrode and are electrically connected to each other,
the first gate electrode and the first threshold adjustment layer are located between a bottom surface of the opening and the first electrode in a plan view of the substrate, and
the second gate electrode and the second threshold adjustment layer are located between a bottom surface of the opening and the second electrode in a plan view of the substrate.

14. The nitride semiconductor device according to claim 13, further comprising:
a p-type fifth nitride semiconductor layer disposed above the semiconductor laminate at a location overlapping the bottom surface of the opening in a plan view of the substrate; and
a third electrode disposed above the fifth nitride semiconductor layer and set to the same potential as the source electrode.

15. The nitride semiconductor device according to claim 9, wherein the first threshold adjustment layer and the second threshold adjustment layer are each a p-type nitride semiconductor layer.

16. The nitride semiconductor device according to claim 9, wherein
the nitride semiconductor device is divided into an active region and an inactive region in a plan view of the substrate;
the first electrode and the second electrode are disposed in the active region;
the nitride semiconductor device further includes:
a first pad disposed in the inactive region and electrically connected to the first electrode; and
a second pad disposed in the inactive region and electrically connected to the second electrode,
all of the first thick film portion, the first thin film portion, and the first threshold adjustment layer are further located between the first electrode and the first pad in a plan view of the substrate,
the first threshold adjustment layer extends across the first thin film portion and the first thick film portion between the first electrode and the first pad in a plan view of the substrate,
all of the first thick film portion, the second thin film portion, and the second threshold adjustment layer are further located between the second electrode and the second pad in a plan view of the substrate, and
the second threshold adjustment layer extends across the second thin film portion and the first thick film portion between the second electrode and the second pad in a plan view of the substrate.

17. A nitride semiconductor device comprising:
a substrate;
an n-type third nitride semiconductor layer disposed above the substrate;
a p-type fourth nitride semiconductor layer disposed above the third nitride semiconductor layer;
a semiconductor laminate disposed to cover an inner surface of an opening penetrating the fourth nitride semiconductor layer and reaching the third nitride semiconductor layer and an upper side of the fourth nitride semiconductor layer, and including a channel;
a first electrode and a second electrode each being in contact with the semiconductor laminate;
a threshold adjustment layer located between the first electrode and the second electrode;
a gate electrode disposed above the threshold adjustment layer; and
a drain electrode disposed below the substrate,
wherein the opening is located between the first electrode and the second electrode in a plan view of the substrate,
the first electrode and the second electrode are each a source electrode and are electrically connected to each other,
the semiconductor laminate includes:
a first nitride semiconductor layer; and
a second nitride semiconductor layer disposed above the first nitride semiconductor layer,
the second nitride semiconductor layer includes:
a first thin film portion located between the gate electrode and the first electrode in a plan view of the substrate;
a second thin film portion located between the gate electrode and the second electrode in a plan view of the substrate; and
a first thick film portion that is located between the first thin film portion and the second thin film portion in a plan view of the substrate and is thicker than both of the first thin film portion and the second thin film portion,
the threshold adjustment layer extends across the first thin film portion and the first thick film portion and extends across the second thin film portion and the first thick film portion in a plan view of the substrate,
an end of the threshold adjustment layer on the first electrode side is located on the first thin film portion, and
an end of the threshold adjustment layer on the second electrode side is located on the second thin film portion.

18. The nitride semiconductor device according to claim 17, wherein
the first electrode is disposed on the first thin film portion, and
the second electrode is disposed on the second thin film portion.

19. The nitride semiconductor device according to claim 17, wherein
the second nitride semiconductor layer further includes:
a second thick film portion located between the first thin film portion and the first electrode in a plan view of the substrate; and
a third thick film portion located between the second thin film portion and the second electrode in a plan view of the substrate,
the first electrode is disposed on the second thick film portion, and
the second electrode is disposed on the third thick film portion.

20. The nitride semiconductor device according to claim 17, wherein
the second nitride semiconductor layer further includes:
a first inclined portion located between the first thin film portion and the first thick film portion in a plan view of the substrate and having an inclined upper surface; and
a third inclined portion located between the second thin film portion and the first thick film portion in a plan view of the substrate and having an inclined upper surface.
